(19) United States
(12) Patent Application Publication
(10) Pub. No.: US 2018/0127865 A1
(43) Pub. Date: May 10, 2018

(54) Nanoparticle Deposition Systems

(71) Applicant: Regents of the University of Minnesota, Minneapolis, MN (US)

(72) Inventors: Jian-Ping Wang, Shoreview, MN (US); Shihai He, Minneapolis, MN (US)

(21) Appl. No.: 15/712,638

(22) Filed: Sep. 22, 2017

Related U.S. Application Data
(62) Division of application No. 13/350,421, filed on Jan. 13, 2012, now abandoned.
(60) Provisional application No. 61/432,421, filed on Jan. 13, 2011.

(51) Int. Cl. C23C 14/22; H01J 37/34; B82Y 40/00; C23C 14/54; C23C 14/35

(52) U.S. Cl. CPC C23C 14/223; H01J 37/3455; H01J 37/345; H01J 37/3438; H01J 37/342; C23C 14/54; C23C 14/35; C23C 14/228; B82Y 40/00

(57) ABSTRACT

Nanoparticle deposition systems including one or more of: a hollow target of a material; at least one rotating magnet providing a magnetic field that controls movement of ions and crystallization of nanoparticles from released atoms; a nanoparticle collection device that collects crystallized nanoparticles on a substrate, wherein relative motion between the substrate and at least a target continuously expose new surface areas of the substrate to the crystallized nanoparticles; a hollow anode with a target at least partially inside the hollow anode; or a first nanoparticle source providing first nanoparticles of a first material and a second nanoparticle source providing second nanoparticles of a second material.

### CROSS-REFERENCE TO RELATED APPLICATION

This application is a divisional of U.S. Ser. No. 13/350,421, filed on Jan. 13, 2012, which claims benefit of priority from U.S. Provisional Application Ser. No. 61/432,421, filed on Jan. 13, 2011.

### TECHNICAL FIELD

This document relates to nanoparticle deposition systems.

### BACKGROUND

Nanoparticles have many applications, including applications in the field of medicine. There are various ways of creating nanoparticles.

### SUMMARY

In a first aspect, a hollow target nanoparticle deposition system includes: a hollow target of a material; a gas source providing ionized gas to an interior of the hollow target; a potential that is applied to at least the hollow target and that causes ions from the ionized gas to impact an interior surface of the hollow target and release atoms of the material; at least one magnet providing a magnetic field that controls movement of the ions and crystallization of nanoparticles from the released atoms; and an outlet of the hollow target where the crystallized nanoparticles exit the hollow target.

Implementations can include any or all of the following features. The hollow target nanoparticle deposition system further includes a ring of another material adjacent the outlet. The ring has a beveled edge facing away from the interior of the hollow target. The magnet is a rotating magnet. The magnet is a tube magnet or hollow magnet. The hollow target nanoparticle deposition system further includes a nanoparticle collection device that is coupled to the outlet and collects the crystallized nanoparticles on a substrate, wherein relative motion between the substrate and at least the hollow target continuously exposes new surface areas of the substrate to the crystallized nanoparticles. The crystallized nanoparticles are first nanoparticles of a first material, and the system further includes: a first nanoparticle source providing the first nanoparticles; a second nanoparticle source providing second nanoparticles of a second material; and a collection chamber with a substrate collecting the first and second nanoparticles; wherein the at least one magnet controls movement of the first and second nanoparticles in the collection chamber.

In a second aspect, a rotating-magnet nanoparticle deposition system includes: a target of a material; a gas source providing ionized gas to the target; a potential that is applied to at least the target and that causes ions from the ionized gas to impact a surface of the target and release atoms of the material; and at least one rotating magnet providing a magnetic field that controls movement of the ions and crystallization of nanoparticles from the released atoms.

Implementations can include any or all of the following features. The target is a hollow target and the gas source provides the ionized gas to an interior of the hollow target. The rotating-magnet nanoparticle deposition system further includes a ring of another material adjacent an outlet of the hollow target where the crystallized nanoparticles exit the hollow target. The ring has a beveled edge facing away from the interior of the hollow target. The rotating-magnet nanoparticle deposition system further includes a nanoparticle collection device that is coupled to the outlet and collects the crystallized nanoparticles on a substrate, wherein relative motion between the substrate and at least the target continuously exposes new surface areas of the substrate to the crystallized nanoparticles. The rotating-magnet nanoparticle deposition system further includes a hollow anode with the target at least partially inside the hollow anode, wherein the gas source provides ionized gas to an interior of the hollow anode. The crystallized nanoparticles are first nanoparticles of a first material, and the system further includes: a first nanoparticle source providing the first nanoparticles; a second nanoparticle source providing second nanoparticles of a second material; and a collection chamber with a substrate collecting the first and second nanoparticles; wherein the at least one rotating magnet controls movement of the first and second nanoparticles in the collection chamber.

In a third aspect, a nanoparticle collection system includes: a target of a material; a gas source providing ionized gas to the target; a potential that is applied to at least the target and that causes ions from the ionized gas to impact a surface of the target and release atoms of the material; at least one magnet providing a magnetic field that controls movement of the ions and crystallization of nanoparticles from the released atoms; and a nanoparticle collection device that collects the crystallized nanoparticles on a substrate, wherein relative motion between the substrate and at least the target continuously expose new surface areas of the substrate to the crystallized nanoparticles.

Implementations can include any or all of the following features. The target is a hollow target and the gas source provides the ionized gas to an interior of the hollow target. The nanoparticle collection system further includes a ring of another material adjacent an outlet of the hollow target where the crystallized nanoparticles exit the hollow target. The ring has a beveled edge facing away from the interior of the hollow target. The magnet is a rotating magnet. The magnet is a tube magnet or hollow magnet. The nanoparticle collection system further includes a hollow anode with the target at least partially inside the hollow anode, wherein the gas source provides the ionized gas to an interior of the hollow anode. The crystallized nanoparticles are first nanoparticles of a first material, and the system further includes: a first nanoparticle source providing the first nanoparticles; and a second nanoparticle source providing second nanoparticles of a second material; wherein the nanoparticle collection device collects the first and second nanoparticles on the substrate.

In a fourth aspect, a hollow-anode nanoparticle deposition system includes: a target of a material; a hollow anode with the target at least partially inside the hollow anode; a gas source providing ionized gas to an interior of the hollow anode; a potential that is applied to at least the target and that causes ions from the ionized gas to impact a surface of the target and release atoms of the material; and an outlet of the hollow anode where nanoparticles crystallized from the released atoms exit the hollow anode.

Implementations can include any or all of the following features. The hollow-anode nanoparticle deposition system further includes at least one rotating magnet providing a magnetic field that controls movement of the ions and crystallization of the nanoparticles from the released atoms. The hollow-anode nanoparticle deposition system further includes a tube magnet or hollow magnet providing a magnetic field that controls movement of the ions and crystallization of the nanoparticles from the released atoms. The hollow-anode nanoparticle deposition system further includes a nanoparticle collection device that is coupled to the outlet and collects the crystallized nanoparticles on a substrate, wherein relative motion between the substrate and at least the target continuously exposes new surface areas of the substrate to the crystallized nanoparticles. The crystallized nanoparticles are first nanoparticles of a first material, the system further including: a first nanoparticle source providing the first nanoparticles; a second nanoparticle source providing second nanoparticles of a second material; a collection chamber with a substrate collecting the first and second nanoparticles; and at least one magnet that controls movement of the first and second nanoparticles in the collection chamber. The hollow anode comprises a tube. The target is a cylinder target.

In a fifth aspect, a multi-source nanoparticle deposition system includes: a first nanoparticle source providing first nanoparticles of a first material; a second nanoparticle source providing second nanoparticles of a second material; a collection chamber with a substrate collecting the first and second nanoparticles; and at least one magnet providing a magnetic field that controls movement of the first and second nanoparticles in the collection chamber.

Implementations can include any or all of the following features. At least one of the first and second nanoparticle sources comprises a hollow target, and a gas source that provides ionized gas to an interior of the hollow target. The multi-source nanoparticle deposition system further includes a ring of another material adjacent an outlet of the hollow target where the first or second nanoparticles exit the hollow target. The ring has a beveled edge facing away from the interior of the hollow target. The magnet is a rotating magnet. At least one of the first and second nanoparticle sources comprises a tube magnet or hollow magnet providing a magnetic field that controls movement of ions and crystallization of the first or second nanoparticles from released atoms. The multi-source nanoparticle deposition system further includes a nanoparticle collection device in the collection chamber, wherein relative motion between the substrate and at least the first and second nanoparticle sources continuously exposes new surface areas of the substrate to the crystallized nanoparticles. At least one of the first and second nanoparticle sources comprises a hollow anode with a target at least partially inside the hollow anode, and the gas source that provides ionized gas to an interior of the hollow anode.

The details of one or more implementations are set forth in the accompanying drawings and the description below. Other features and advantages will be apparent from the description and drawings, and from the claims.

### DESCRIPTION OF DRAWINGS

FIG. 1 shows a cross-sectional view of an example tube target nanoparticle deposition system that uses an iron ring.

FIG. 2 shows a cross-sectional view of an example tube target nanoparticle deposition system that includes cooling water and a power supply.

FIG. 3 shows a cross-sectional view of an example tube target nanoparticle deposition system for depositing nanoparticles onto a substrate in a collection chamber.

FIGS. 4A-4B show perspective views of an example tube target nanoparticle deposition system.

FIG. 5 shows a graph that plots an example change of pressure line for sputtering gas that passes through a tube-shaped target

FIG. 6 shows a graph that plots example changes in temperature and concentration of sputtered atoms relative to target position.

FIG. 7A shows a perspective view of an example simulation model of a tube target nanoparticle deposition system.

FIG. 7B shows a perspective view of an example simulation model of a tube target nanoparticle deposition system with a beveled target opening.

FIG. 8 shows a cross-sectional view of an example flat target nanoparticle deposition system with rotating magnets.

FIG. 9 shows a cross-sectional view of an example ring-shape-target nanoparticle deposition system for depositing nanoparticles onto a substrate in a collection chamber.

FIG. 10 shows a cross-sectional view of an example automatic nanoparticle collection system.

FIG. 11 shows an example multi-source nanoparticle deposition system for nanoparticle-assemblies.

FIG. 12 shows an example magnetic field that can be produced by a ring-shaped magnet.

FIG. 13 shows a cross-sectional view of an example magnetic field that can be produced by magnets in a North-to-South arrangement.

FIG. 14 shows a cross-sectional view of an example magnetic field that can be produced by magnets in a North-to-North arrangement.

FIG. 15 shows a graph of an example pressure simulation of gas flow in a tube cathode.

FIG. 16 shows an example velocity field simulation that indicates the speed and direction of a gas flow through a tube target.

FIGS. 17A-C show example velocity field simulations for gas flow through tube targets.

FIG. 18 shows a cross-sectional view of an example magnetic field that can be produced by magnets in a North-to-North arrangement and adding an iron ring.

FIGS. 19A and 19B show side views of an example tube target nanoparticle deposition system, and the back view of its cooling part.

FIG. 20 shows example FeCo nanoparticles that were produced using tube target nanoparticle deposition systems.

FIG. 21 shows images for example Fe—N nanoparticle samples created using a tube target.

FIG. 22 shows a cross-sectional view of an example nanoparticle deposition system that uses a nucleation target and growth targets for same or different layers on the nucleus.

FIG. 23 shows a cross-sectional view of an example nanoparticle deposition system that uses a nucleation target and a cylinder-shaped plasma control magnet.

FIG. 24 shows a more detailed cross-sectional view of the nucleation target and the cylinder-shaped plasma control magnet.

FIG. 25 shows a cross-sectional view of an example nanoparticle deposition system that uses a nucleation target and a U-shaped plasma control magnet.

FIG. 26 shows a more detailed cross-sectional view of the nucleation target and the U-shaped plasma control magnet.

FIG. 27 shows a nanoparticle fabrication source using a tube-shaped magnet.

FIG. 28 shows a nanoparticle fabrication source using a dumbbell magnet.

FIG. 29 shows a nanoparticle fabrication source using a cylinder target in source center as the cathode.

Like reference symbols in the various drawings indicate like elements.

### DETAILED DESCRIPTION

This document describes nanoparticle deposition systems and methods that are scalable for mass production. For example, inside hollow targets (such as inside a tube target, or near targets of other shapes) target atoms are ejected from the target due to the bombardment of argon ions which are generated by the ionization of Argon gas (e.g., the supplied sputtering gas). The sputtered atoms form atom gas, and the gas condenses to form nanoparticles. The formed nanoparticles can be carried with a carrier gas and deposited on any suitable substrate, including nanoparticle-assembled films. One or more magnets can create magnetic fields around each target, controlling the formation of the nanoparticles. A tube target is mentioned in some examples herein, but in some implementations another hollow target can be used that is not tubular.

Sputtering inside the hollow target and controlling the direction of movement of the nanoparticles can facilitate an automatic nanoparticle collection setup and handling process. Multi-part (e.g., two-part) cooling systems can cool the targets during the sputtering/deposition process.

In some implementations, one or more rotating magnetron sources can be used for nanoparticle deposition. For example, rotating magnets can provide a magnetic field to different areas of a single target or to multiple targets such as targets arranged in a circle.

In some implementations, multi-source integrated nanoparticle deposition system can funnel particles of different types through a magnetic field to a substrate or compression die. As a result, particles having different characteristics can be manufactured and collected simultaneously.

In some implementations, a tube-array can be used, such as in large-scale fabrication for producing large amounts of nanoparticles. For example, a large number (e.g., hundreds or more) of small tubes can be used for nanoparticle deposition.

The systems described in this document can use gas phase condensation techniques based on one or more sputtering sources to fabricate several kinds of nanoparticles that cannot be made by other methods, including FeCo, FeCo—FeCoO, FeCo—Au, FeCo—SiO₂, Fe—Ag, Co—Au, C, and Fe—Au, to name a few examples.

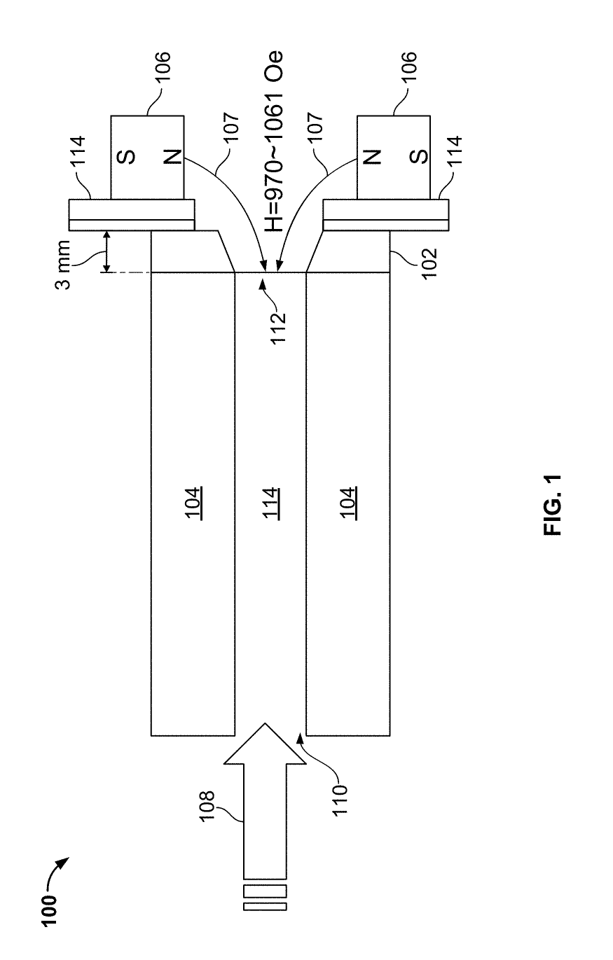

FIG. 1 shows a cross-sectional view of an example tube target nanoparticle deposition system 100 that uses an iron ring 102. The system 100 includes a tube-shaped target 104, which in this example is FeCo (i.e., iron-cobalt), but other types of iron alloys can be used. In some implementations, the target 104 can have a length of 40 mm, an outer diameter of 20 mm, and a hole diameter of 5 mm. A magnet 106 can provide a magnetic field 107 in the area of the target 104. The magnetic field 107, depicted with two arrows, can extend throughout most or all of the area inside the target 104.

A gas 108 (e.g., argon) can be introduced into a tube entrance 110 of the target 104. The gas 108 can be ionized and pass through a plasma region (e.g., nanoparticle-forming region) that is formed by the hollow region of the target 104. Positively-charged ions in the gas can be accelerated by the negative potential at the target 104 and knock out the atoms of the target, leading the formation of atom gas. Then the atom gas can condense to form nanoparticles. The crystallization of the nanoparticles can be carried out in the thermal environment of the plasma. “Plasma” can refer to the gas 108 that contains formed nanoparticles. The magnetic field 107 can serve to control the movement of the positively-charged ions and the crystallization of the nanoparticles. As a result, erosion of the outside of the target 104 can be minimized, such as at an outlet end 112 of the target 104. For example, in experiments performed without the iron ring 102, after four hours of sputtering (900 mTorr and 0.9 A), the outside surface diameter of the hole at the outlet end 112 changed from 5 mm to 5.1 mm.

The iron ring 102, positioned between the magnet 106 and the target 104, can serve to intensify and guide the magnetic field 107 to the inner surface of the target 104. A ring-shaped anode 114 can be positioned between the magnet 106 and the iron ring 102. Having the iron ring 102 positioned in this way can serve to elongate a plasma region 114 in the interior of the target 104, which in turn can increase the crystallization time. Nanoparticles that are formed can exit the plasma region 114, passing through openings of the iron ring 102, the anode 114, and the magnet 106. The formed nanoparticles can be deposited on a substrate or some other collection device that is not shown in FIG. 1.

Some implementations of the iron ring 102 can include a beveled edge as shown in FIG. 1. Other edge shapes of the iron ring 102 can be used to achieve different results in the magnetic field. The iron ring 102 can be 3 mm thick, for example, or other thicknesses can be used in order to achieve different results.

In some implementations, the strength of the magnetic field (or H-field) can be in the range of 970 to 2000 Oe and can depend, for example, on the requirement of nanoparticle growth condition. For example, stronger magnets can be selected for thicker iron rings for which a larger magnetic field is desired. Magnet selection can also depend on the particle size that is desired for the formed nanoparticles. Longer targets can increase the crystallization time and produce larger nanoparticles. Thicker magnets can increase the growth time and produce larger nanoparticles.

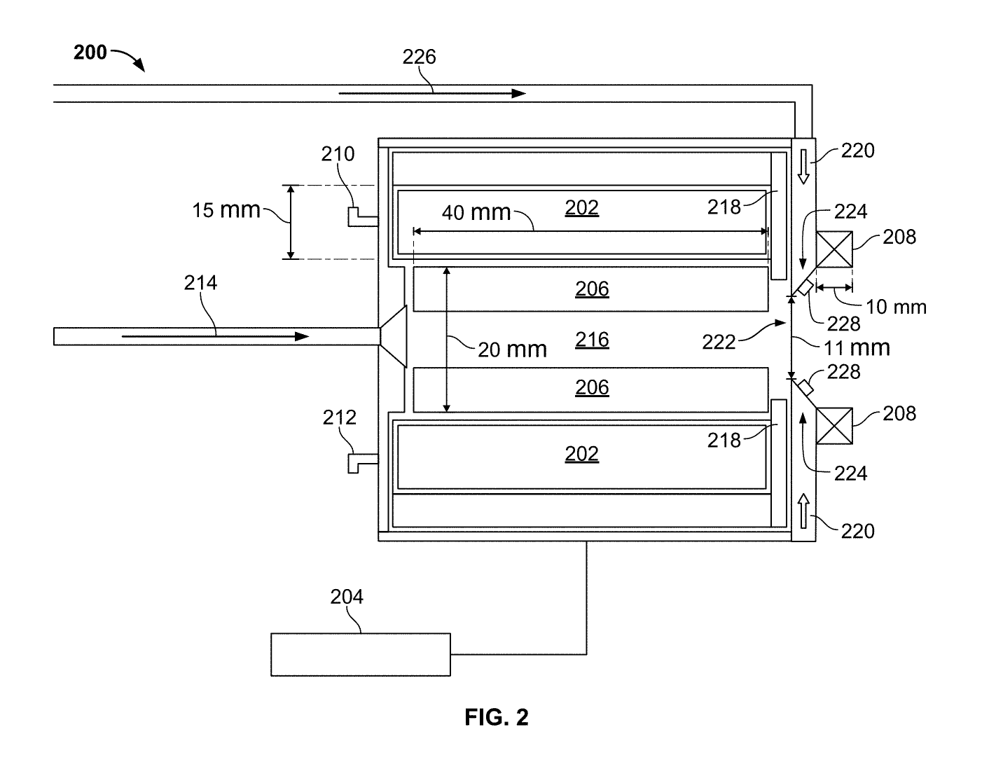

FIG. 2 shows a cross-sectional view of an example tube target nanoparticle deposition system 200 that includes cooling water 202 and a power supply 204. The system 200 includes a tube-shaped target 206 and magnets 208 that provide a magnetic field in the area of the target 206. The target 206 in the system 100 can be, for example, 40 mm long and 20 mm wide, but other size targets 206 can be used. The magnet 208 can be 10 mm thick, but magnets 208 having other thicknesses can be used.

The cooling water 202 can circulate and cool the target 206. For example, the cooling water 202 can be contained within in a cooling chamber (e.g., cylindrically-shaped) that surrounds the tube-shaped target 206. The cooling water 202 can enter the cooling chamber through an inlet 210 and exit through an outlet 212. Other configurations of inlets 210 and outlets 212 can be used to provide cooling water 202 or some other coolant for cooling the target 206. In some implementations, the cooling chamber can be partitioned in such a way to generally circulate the cooling water 200 primarily from the inlet 210 to the outlet 212. The configuration of inlets 210, outlets 212 and cooling chambers can be part of various multi-part cooling systems.

A gas 214 (e.g., argon) can be introduced into the tube area of the target 206. The gas 214 can be ionized and can pass through a plasma region 216 that is formed by the hollow region of the target 206. Positively-charged ions in the gas 214 can be accelerated by the negative potential at the target 206 and knock out the atoms of the target, leading to formation of atom gas. Then the atom gas can condense to form nanoparticles. The crystallization of the nanoparticles can be carried out in the thermal environment of the plasma. The magnetic field can serve to control the movement of the positively-charged ions and the crystallization of the nanoparticles.

A ceramic insulator 218, which can be positioned between a ring-shaped anode 220 and the target 206, can serve to separate the target 206 from the grounded, ring-shaped anode 220. The target 206 can be charged by the power supply 204. The thickness of the ceramic insulator 218 can serve to elongate the plasma region 216 in the interior of the target 206 which also extends to the opening of the anode 220, which in turn can increase the crystallization time. Nanoparticles that are formed can exit the plasma region 216, passing through openings in the ceramic insulator 218, the anode 220, and the magnets 208. The nanoparticles can be deposited on a substrate or some other particle collection device that is not shown in FIG. 2.

Some implementations of the anode 220 can include a beveled inner edge 224 as shown in FIG. 2. Other edge shapes can be used for the anode 220. The opening formed by the inner edge 224 can be 11 mm thick, for example, or some other thickness in order to achieve different results.

A carrier gas 226 can be introduced into the target system 200 to direct nanoparticle-containing gas (e.g., plasma) away from the target 206 and toward a nanoparticle collection mechanism such as a substrate. Nozzles 228 on the beveled edges of the anode 220 can direct the carrier gas 226 generally away from the area of the target 216, and can serve to help pull the gas 214 away from the target 206.

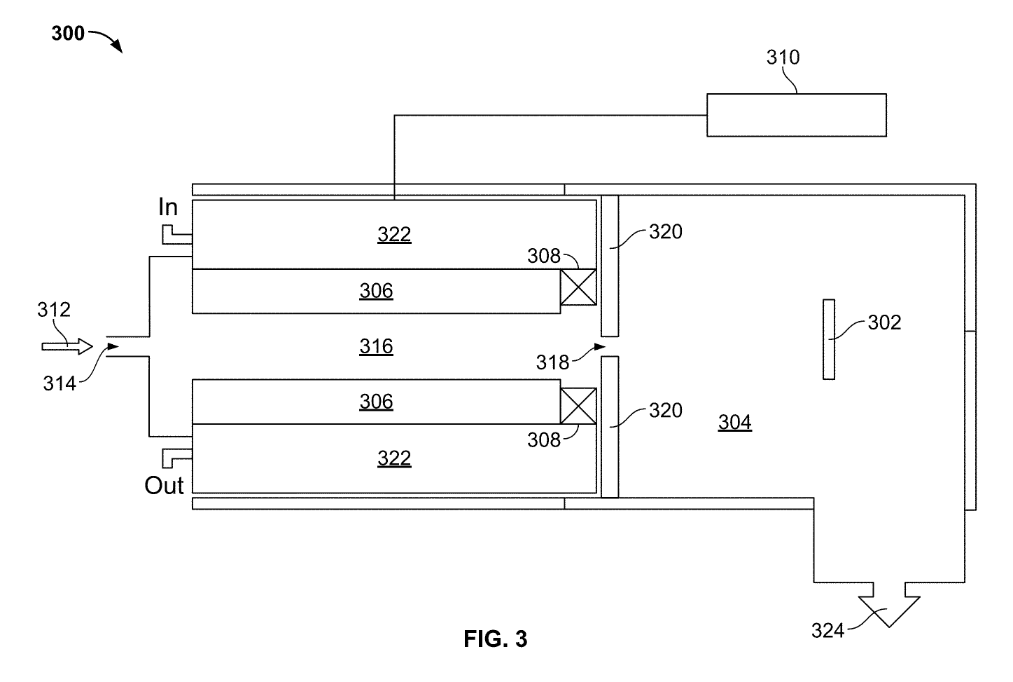

FIG. 3 shows a cross-sectional view of an example tube target nanoparticle deposition system 300 for depositing nanoparticles onto a substrate 302 (e.g., a disk) in a collection chamber 304. The system 300 includes a tube-shaped target 306 and a solenoid 308. A power supply 310 can provide an electric current to (and through) the solenoid 308 to produce a magnetic field in the area of the target 306.

Ionized argon gas 312 can be pumped through an opening 314 into a plasma region 316 inside the tube of the target 306. Positively-charged ions in the gas 312 can be accelerated by the negative potential at the target 306 and knock out the atoms of the target, leading the formation of atom gas. Then the atom gas can condense to form nanoparticles. The crystallization of the nanoparticles can be carried out in the thermal environment of the plasma. The gas 312 can carry the nanoparticles through an opening 318 into the collection chamber 304. The opening 318 can be at or near an ejection area of the target 306. The opening 318 can be formed in a barrier 320 that separates the collection chamber 304 from the area in the system 300 that houses the target 306 and the cooling water 322. The substrate 302 can be positioned relative to the opening 318 so that most or all of the nanoparticles are directed toward the substrate 302 where the nanoparticles can be deposited. A pump 324 can continuously pull or draw the remaining argon gas 312 through and out of the chamber 304. The pump 324 can also increase the flow rate of the gas 312 through the target 306.

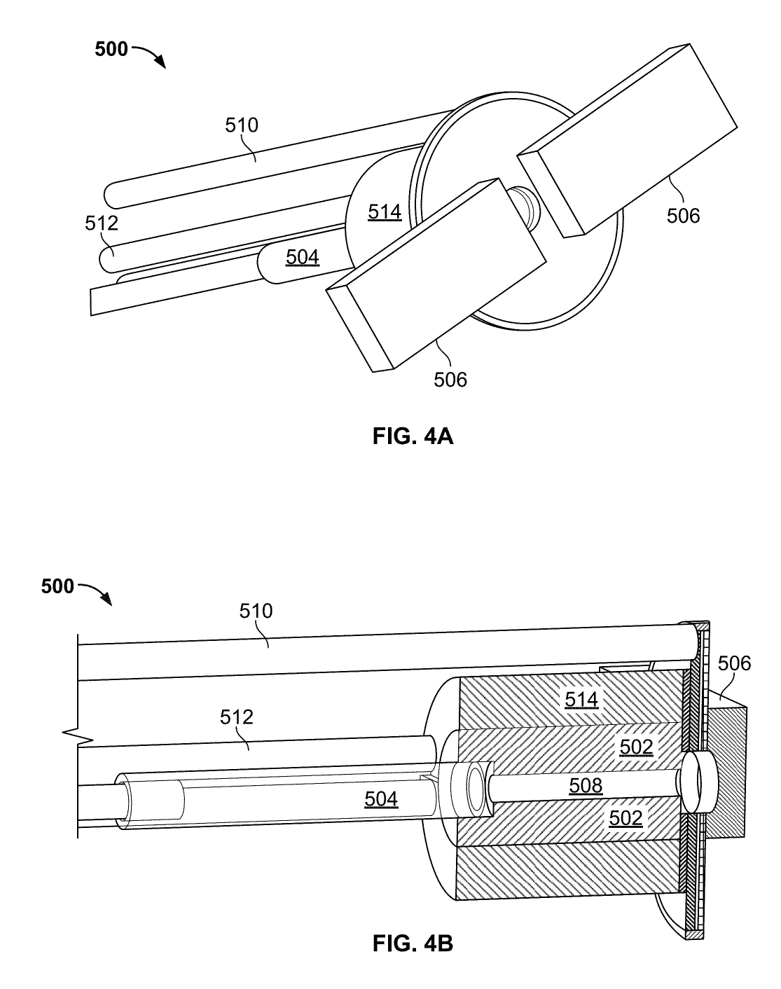

FIGS. 4A-4B show perspective views of an example tube target nanoparticle deposition system 500. The view of the system 500 in FIG. 4A is also a cross-sectional view. The system 500 includes a target 502 through which sputtering gas 504 can be provided (e.g., through a tube, using a pump). Magnets 506 can provide a magnetic field that affects the production of nanoparticles that are formed in a plasma area 508 inside the target 502. A carrier gas 510 can be expelled near the outlet end of the target 502. For example, the carrier gas 510 can be expelled at an angle that is, at least in part, directed away from the target 502. As a result, the carrier gas 510 can help to carry the nanoparticles away from the target 502, such as toward a substrate or other collection device onto which the nanoparticles are deposited. Cooling water 512 can be pumped into a water chamber 514 where the cooling water 512 can cool the target 502.

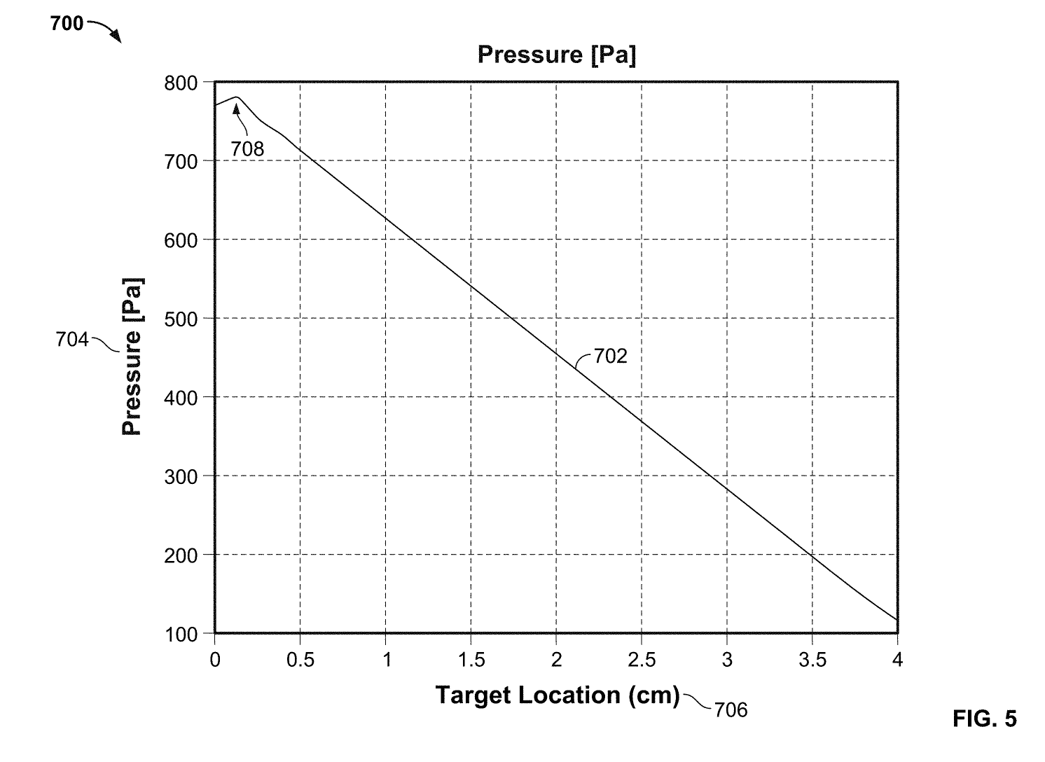

FIG. 5 shows a graph 700 that plots an example change of pressure line 702 for sputtering gas that passes through a tube-shaped target. For example, the graph 700 can represent the change in pressure of sputtered gas in any of the tube-shaped targets (e.g., targets 104, 206, 306, etc.) described in this document. The graph 700 includes a pressure vertical axis 704 and a location horizontal axis 706. Points on the location horizontal axis 706 correspond to locations within the target, starting at 0 cm, where the sputtered gas enters the target, to 4 cm at the ejection end of the target. As shown by the change of pressure line 702, the pressure can start high (e.g., around 5.79 Torr at location 0 cm). The pressure can then rise to a peak 708 (e.g., at a pressure of about 5.85 Torr at location near 0.17 cm), then fall relatively linearly through the remainder of the target (e.g., to a pressure of about 0.877 Torr at location 4 cm). In another example, the gas pressure can decrease continuously from a starting pressure of 10.5 Torr at the entrance area of the target to 1.3 Torr at the ejection area of the target.

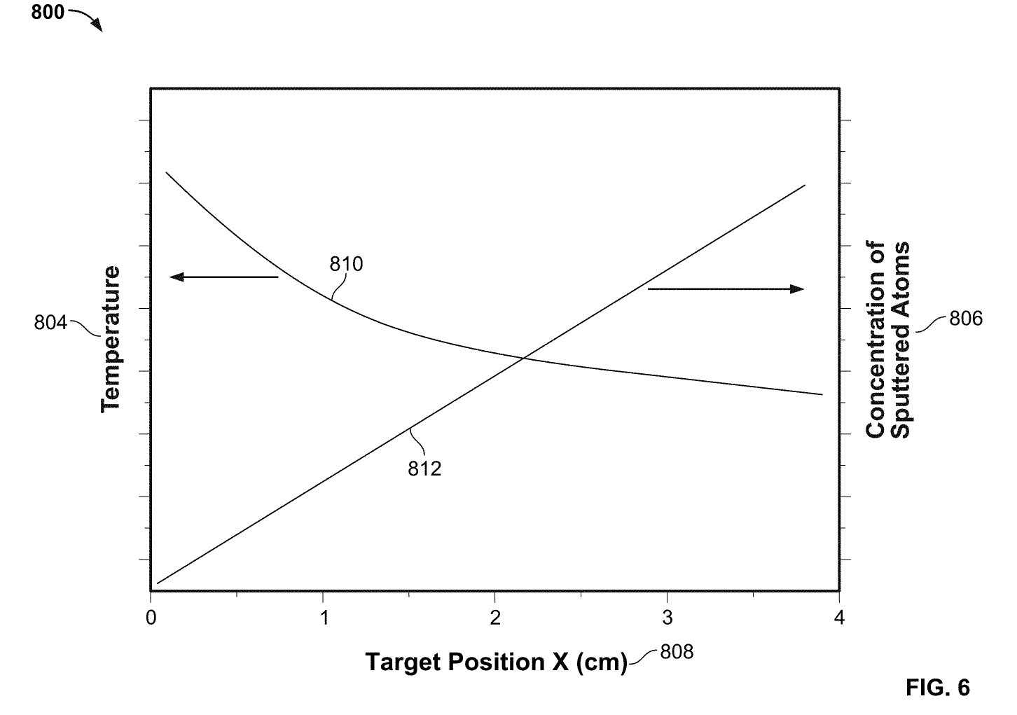

FIG. 6 shows a graph 800 that plots example changes in temperature and concentration of sputtered atoms relative to target position. For example, the graph 800 can represent the change in temperature of sputtered gas and sputtered atom concentrations in any of the tube-shaped targets (e.g., targets 104, 206, 306, etc.) described above with reference to FIGS. 1-3 and 4A-B. The graph 800 includes a temperature vertical axis 804, an atom concentration vertical axis 806, and a target position horizontal axis 808. Points on the target position horizontal axis 808 correspond to positions within the target, starting at 0 cm, where the sputtered gas enters the target, to 4 cm at the ejection end of the target. As shown by a change of temperature line 810, the temperature is highest at 0 cm and begins to drop. The rate of temperature decrease slows over time, and the temperature is lowest at the 4 cm position. A concentration line 812 shows a generally linear and increasing concentration of sputtered atoms. The concentration increases from the entrance to the target (0 cm) to the ejection end of the target (4 cm).

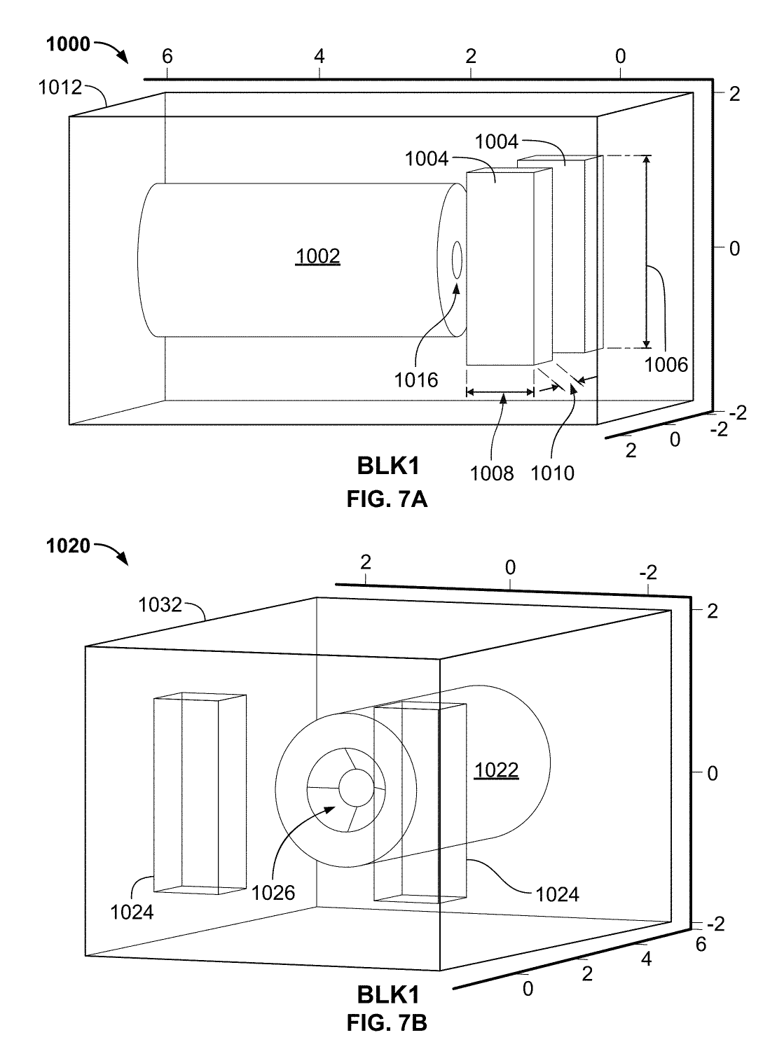

FIG. 7A shows a perspective view of an example simulation model of a tube target nanoparticle deposition system 1000. The system 1000 includes a tube-shaped target 1002 and two external magnets 1004 that can create a magnetic field in the area of the target 1002. The outer diameter of the target 1002 is about half the length of the target 1002. For example, if the target 1002 is 40 mm long, the diameter of the target 1002 can be about 20 mm. Using this size target 1002, for example, the magnets 1004 can be positioned about 10 mm from the ejection end of the target 1002. Furthermore, the magnets 1004 can have a height 1006 of about 30 mm, a depth 1008 of about 10 mm, and a width 1010 of about 10 mm. Also, the space between the magnets 1004 can be 10 mm. Other dimensions of (and/or spaces between) the target 1002 and the magnets 1004 can be used in other implementations. A cube 1012 around the target 1002 and the two external magnets 1004 can represent a nanoparticle growth chamber.

FIG. 7B shows a perspective view of an example simulation model of a tube target nanoparticle deposition system 1020 with a beveled target opening. The system 1020 can be similar to the tube target system 1000. For example, a tube-shaped target 1022 can be about 40 mm long. Magnets 1024 can have similar sizes as the magnets 1004 and can be approximately the same distance from the target 1022. However, the target 1022 can have a beveled ejection end 1026 as opposed to a 90-degree or straight-cut ejection end 1016 of the target 1002. Other shapes of the target 1022 can be used in other implementations. A cube 1032 around the target 1022 and the two external magnets 1024 can represent a nanoparticle growth chamber.

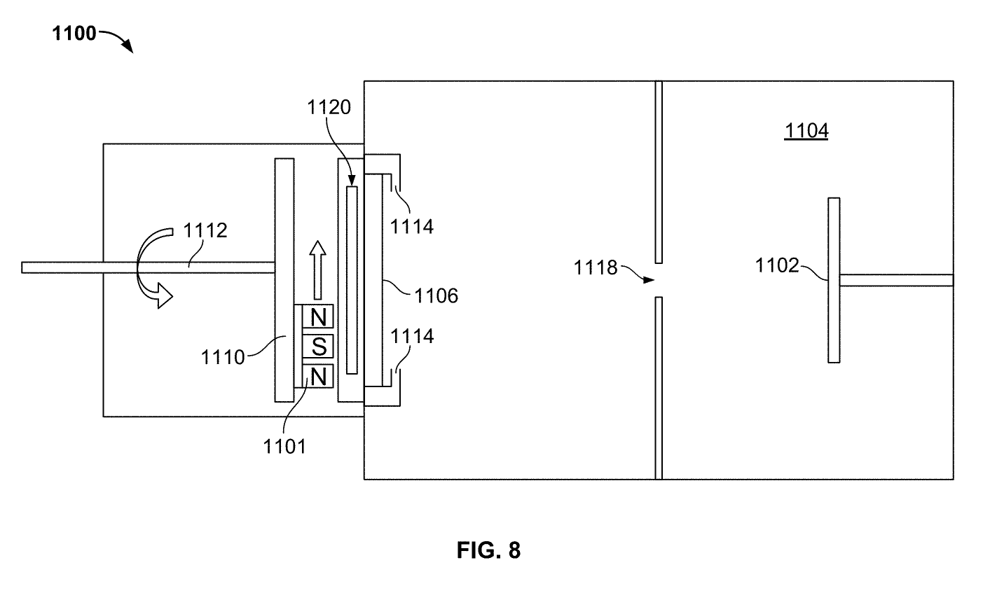

FIG. 8 shows a cross-sectional view of an example flat target nanoparticle deposition system 1100 with rotating magnets 1101. The system 1100 can deposit nanoparticles onto a substrate 1102 (e.g., a disk) in a collection chamber 1104. The system 1100 includes a flat target 1106, which can be a round, relatively flat disk, for example. The rotating magnets 1101 can produce a magnetic field in the area of the target 1106. The rotating magnets 1101 can be mounted on a flat disk 1110 that rotates in tandem with an axis 1112 that is attached to the flat disk 1110. For example, the axis 1112 can be operated by a motor or some other driving mechanism for providing rotation of the axis 1112. In some implementations, the rotating magnets 1101 can rotate at a rate that provides a sufficient magnetic field on and about the target 1106 in order to provide for effective sputtering from a gas supply 1114. For example, the gas supply 1114 can provide ionized argon gas into the area of the target 1106.

During the sputtering process, positively-charged ions within gas from the gas supply 1114 can be accelerated by the negative potential at the target 1106 and knock out the atoms of the target, leading to the formation of atom gas. Then the atom gas can condense to form nanoparticles. The crystallization of the nanoparticles can be carried out in the thermal environment of the plasma. The gas from the gas supply 1114 can carry the nanoparticles through an opening 1118 into the collection chamber 1104. The opening 1118 can be aligned with the midpoint of the target 1106. The substrate 1102 can be positioned relative to the opening 1118 so that most or all of the nanoparticles are directed toward the substrate 1102 where the nanoparticles can be deposited. Cooling water 1120 can be used to cool the target 1106.

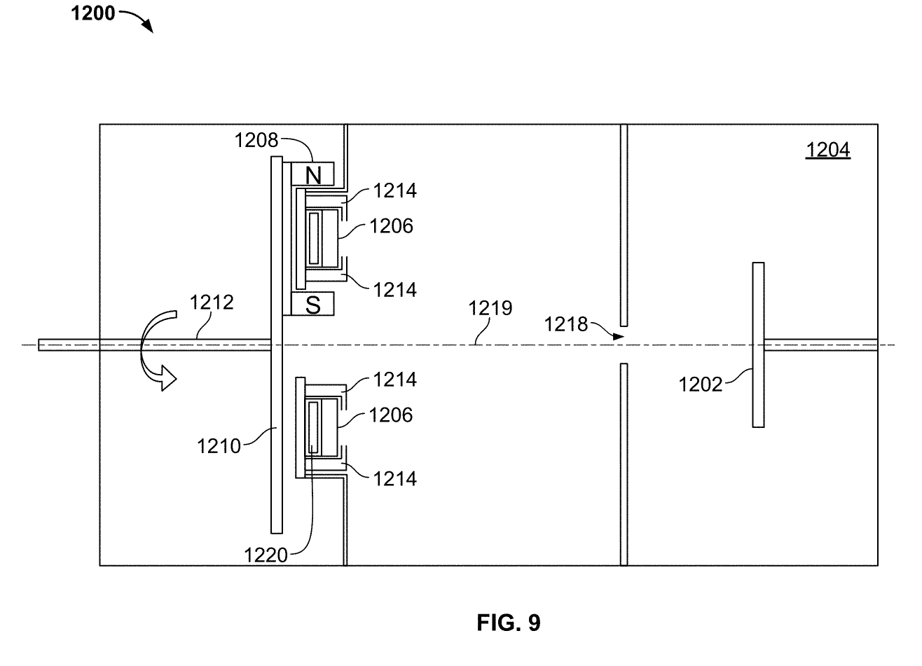

FIG. 9 shows a cross-sectional view of an example ring-shape-target nanoparticle deposition system 1200 for depositing nanoparticles onto a substrate 1202 (e.g., a disk) in a collection chamber 1204. The system 1200 uses a ring shape target 1206. A set of rotating, wrap-around magnets 1208 can produce a magnetic field near the surface of the targets 1206. The magnets 1208 differ from the rotating magnets 1101 (FIG. 8), for example in that the magnets 1208 partially wrap-around the targets 1206, unlike the rotating magnets 1101, which are completely behind the target 1106. The magnets 1208 can be mounted on a flat disk 1210 that rotates in tandem with an axis 1212. For example, the axis 1212 can be operated by a motor or some other driving mechanism for providing rotation of the axis 1212. In some implementations, the rotating wrap-around magnets 1208 can rotate at a rate that provides a sufficient magnetic field around the target 1206 in order to provide for effective sputtering from a gas supply 1214 (e.g., ionized argon gas).

During the sputtering process, positively-charged ions within the gas from the gas supply 1214 can be accelerated by the negative potential at the targets 1206 and knock out the atoms of the target, leading to the formation of atom gas. Then the atom gas can condense to form nanoparticles. The crystallization of the nanoparticles can be carried out in the thermal environment of the plasma. The gas from the gas supply 1214 can carry the nanoparticles through an opening 1218 into the collection chamber 1204. The opening 1218 can be at or near a centerline 1219 that aligns with the axis 1212. The centerline 1219 can also define the center point of a circle in which the multiple targets 1206 are arranged. Each target 1206 in the circle can be accessible by the wrap-around magnets 1208 that travel in a path relative to the circle. The substrate 1202 can also be positioned along the centerline 1219 and aligned with the opening 1218 so that most or all of the nanoparticles are directed toward the substrate 1202 where the nanoparticles can be deposited. Cooling water 1220 can be used to cool the target 1206.

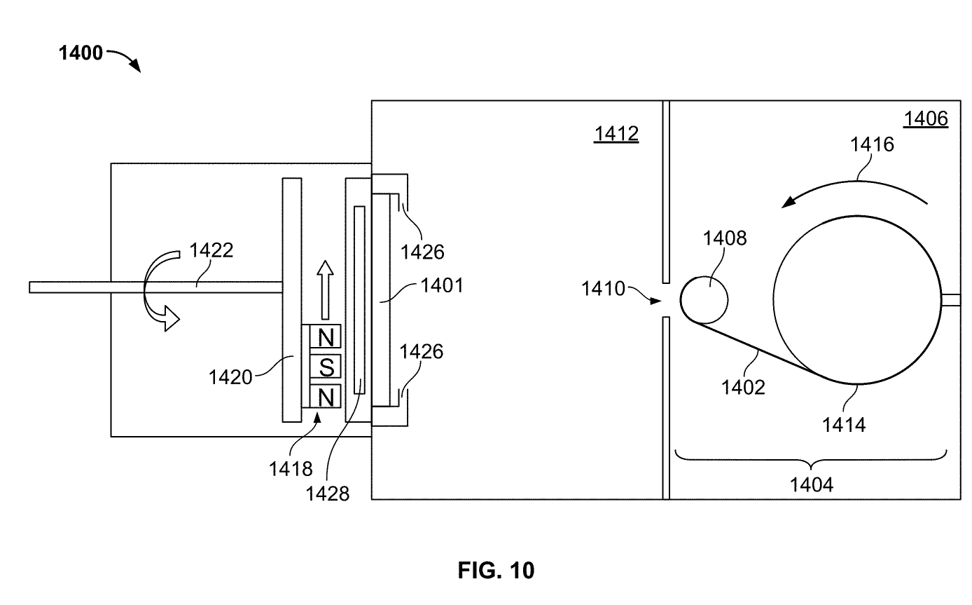

FIG. 10 shows a cross-sectional view of an example automatic nanoparticle collection system 1400. During a process that includes sputtering near a target 1401, nanoparticles can be deposited on a substrate 1402 that is mounted on and continuously fed by an automatically-controlled roller system 1404 inside a collection chamber 1406. Nanoparticles can be deposited on a portion of a long, flexible substrate material (e.g. a water-soluble polymer, etc.) that serves as the substrate 1402. The substrate material can be mounted on a small roller 1408 that is positioned near an opening 1410 between a target chamber 1412 and the collection chamber 1406. Over time, a large roller 1414 can slowly (but continuously) rotate, pulling deposited-upon portions of the substrate 1402 from the small roller 1408 and exposing clean sections of the substrate material. In the example shown in the cross-sectional view of FIG. 10, both rollers rotate in a counter-clockwise direction, as indicated by a directional arrow 1416. In this example process that uses the long substrate on the roller system 1404, the system 1400 can collect a significant amount of nanoparticles for a long time (e.g., hundreds of hours) without interruption to change the substrate. In some implementations, the nanoparticle source can be replaced by a tube target or other design.

The system 1400 includes magnets 1418, e.g., in a North-South-North configuration, that can be mounted on a rotating mounting disk 1420. The mounting disk 1420 can rotate in response to the rotation of a rotating axle 1422 to which the mounting disk 1420 is attached. The mounting disk 1420 can be essentially parallel to the negatively-charged target 1401. As the set of magnets 1418 is rotated on the mounting disk 1420, a magnetic field can be produced by the magnets 1418. The magnetic field can affect the movement of ions near gas supplies 1426 that can pump gas (e.g., argon) into the area around the target 1401. The gas supplies 1426 can release an Argon gas in proximity to the negatively-charged target 1401. Cooling water 1428 can cool the target 1401 during the sputtering process. In some implementations, other configurations of the magnets 1418 can be used, including various arrangements of different magnetic polarities, in order to provide different magnetic fields around the target 1401.

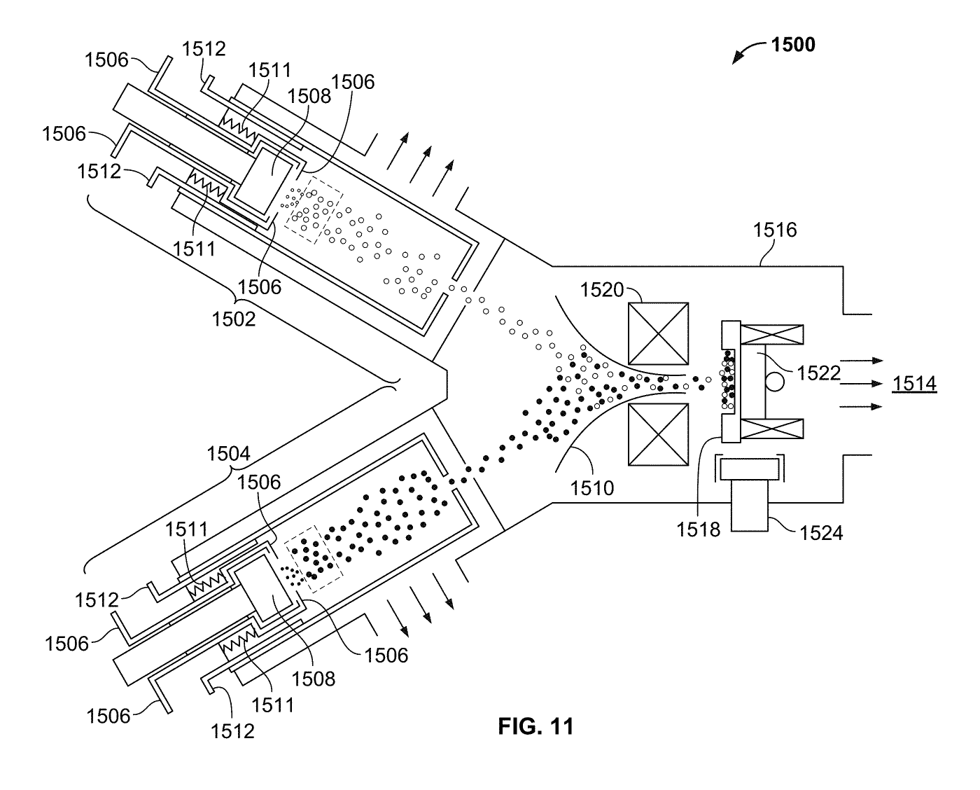

FIG. 11 shows an example multi-source nanoparticle deposition system 1500 for nanoparticle-assemblies. In this example, each of two nanoparticle sources 1502 and 1504 have a sputtering gas supply and a target 1508, providing nanoparticles in the direction of a funnel 1510. For example, the nanoparticle sources 1502 and 1504 can provide nanoparticles of different types (e.g., metals) and characteristics (particle size).

Solenoids 1511 or some other source(s) can provide a magnetic field in the area of each target 1508. Carrier gas supplies 1512 can aid in carrying the nanoparticles in the direction of the funnel 1510. A pump 1514 attached to a collection chamber 1516 can serve to pull the nanoparticles through the funnel 1510 and toward a substrate 1518. For example, the substrate 1518 can be a substrate (e.g., a disk or water-soluble polymer, etc.), a collection die, or some other particle-collecting surface. The nanoparticles that are collected on the substrate 1518 can be used, for example, in biomedical or other applications. Other example substrates 1518 include flexible substrates for solar cell applications and a solid substrate on a nanocomposite magnet for Micro-Electro-Mechanical Systems (MEMS) or Nano-Electro-Mechanical Systems (NEMS) applications. In some implementations, one or more of the nanoparticle sources 1502 and 1504 can be replaced with a tube design or other designs.

The funnel 1510 can be surrounded by a magnetic coil 1520 that can create a magnetic field around the funnel 1510. A heater 1522 can heat the substrate 1518, e.g., to enhance the collection of nanoparticles on the substrate 1518. A sputtering gun 1524 can provide an additional gas (e.g., argon containing ionized atoms) into the collection chamber 1516 in the direction of the substrate 1518. Atoms within the gas from the sputtering gun 1524 can mix with the nanoparticles produced by the nanoparticle sources 1502 and 1504 to produce composite materials.

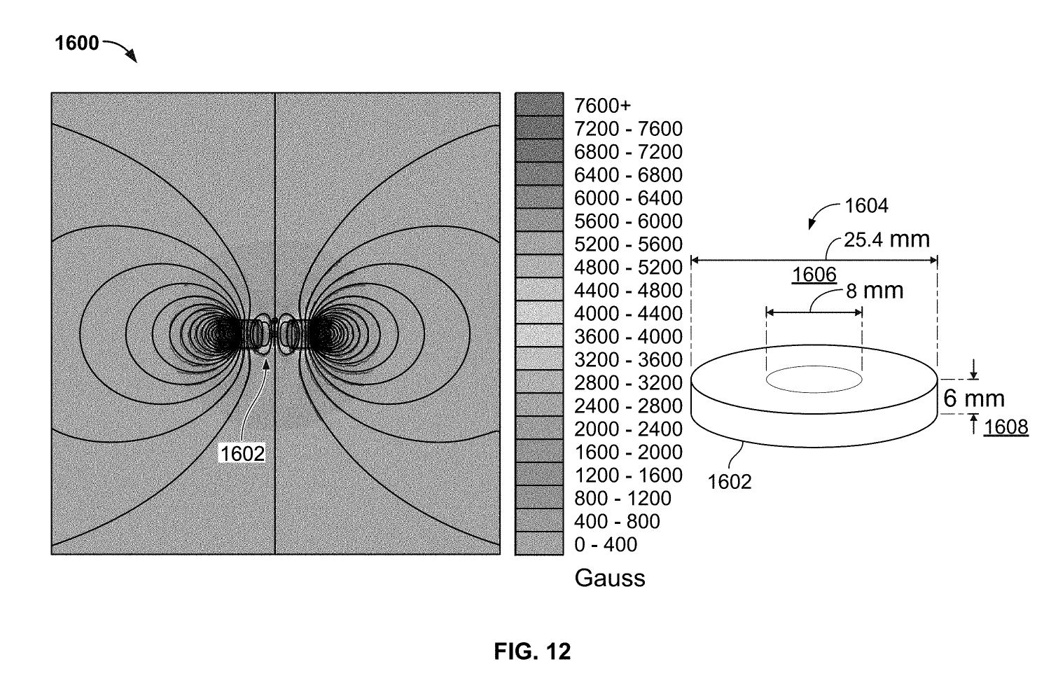

FIG. 12 shows an example magnetic field 1600 that can be produced by a ring-shaped magnet 1602. For example, the magnet 1602 can be used by various nanoparticle deposition systems described in this document. The magnet 1602 can have a width 1604 of 25.4 mm, a hole diameter 1606 of 8 mm, and a thickness 1608 of 6 mm. This is just one example magnet that can be used by nanoparticle deposition systems described in this document, as magnets with other dimensions can also be used. Attaching a ring magnet (e.g., the magnet 1602) to the surface of a tube target can produce a magnetic field within the target that is suitable for creating nanoparticles. Magnets can be changed as needed to change the strength of the magnetic field.

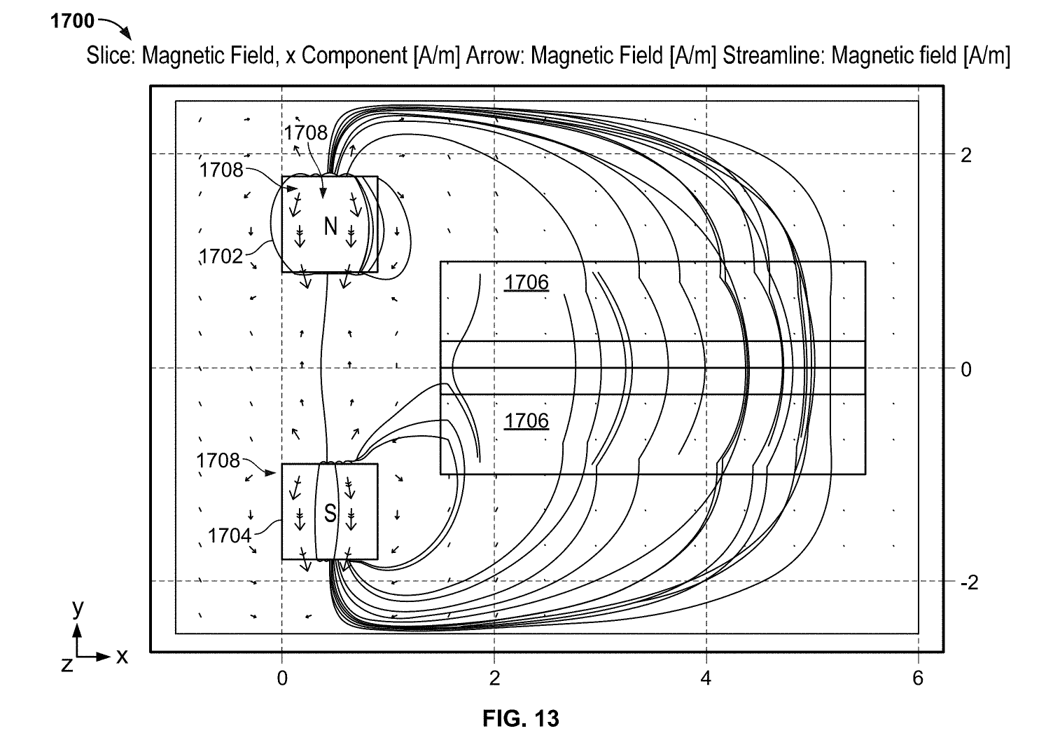

FIG. 13 shows a cross-sectional view of an example magnetic field 1700 that can be produced by magnets 1702 and 1704 in a North-to-South arrangement. The magnetic field 1700 can extend into the area of a tube target 1706. For example, the magnetic field 1700 is here represented with arrows 1708 from the “N” (north) magnet 1702 to the “S” (south) magnet 1704, as well as magnetic field stream lines that intersect the target 1706. By adopting a North-to-South magnet arrangement, for example, the maximum of B, indicating magnetic induction, can be located far away from surface of the target 1706. As a result, plasma can be drawn out of the target 1706. The nanoparticles can grow under a low temperature environment and can have a low crystallinity.

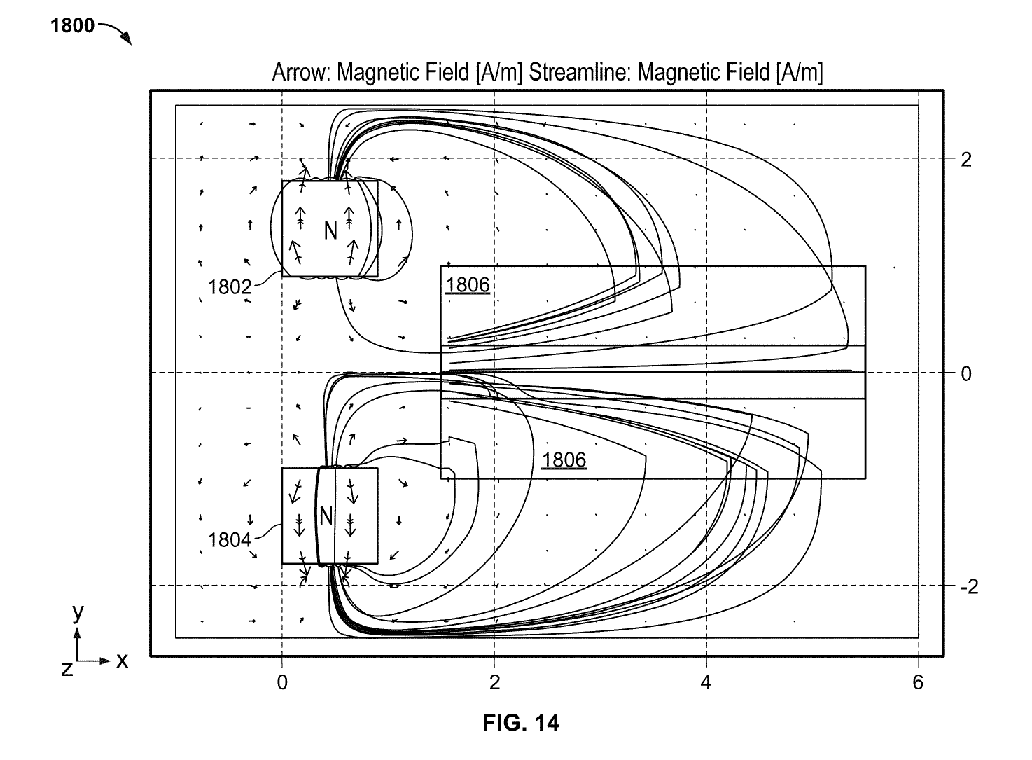

FIG. 14 shows a cross-sectional view of an example magnetic field 1800 that can be produced by magnets 1802 and 1804 in a North-to-North arrangement. The magnetic field 1800 can extend into the area of a tube target 1806. By adopting a North-to-North magnet arrangement, for example, the region with maximum B is moved to the outlet hole of the target 1806. Experiments have shown that nucleation and growth can also occur at the outlet hole of the target, meaning that nucleation and growth can occur in a high-density plasma region.

The use of a ring magnet in this example can create a magnetic field that is parallel to the long axis of a tube target (e.g., the target 1806). Also, the region with the strongest magnetic field can be close to the outlet of the tube target.

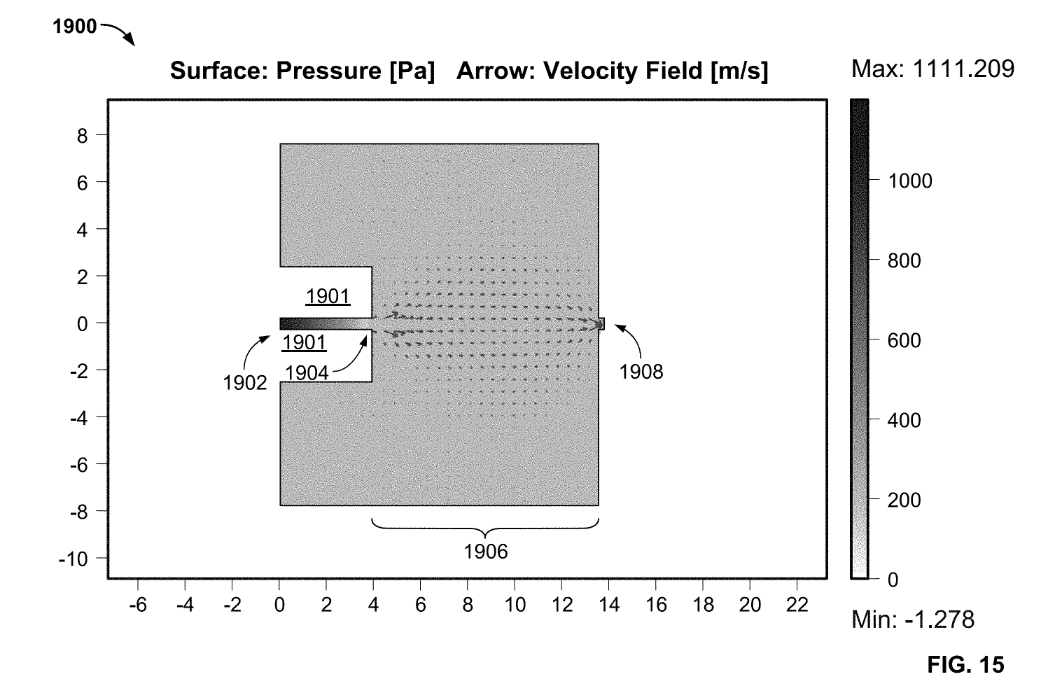

FIG. 15 shows a graph 1900 of an example pressure simulation of gas flow in a tube cathode. The graph 1900, for example, shows that the pressure field can be non-uniform inside a tube target 1901. A location 1902 can represent the location at the opening of the tube target 1901 into which ionized gas is introduced. At the location 1902, the pressure of the gas can generally be at its highest. A location 1904 can represent the ejection area of the tube target 1901. By the time the gas reaches the location 1904, the pressure can drop significantly. For example, there can be a relatively linear drop in pressure between the locations 1902 and 1904. A region 1906 can represent, for example, the region between the ejection end of a tube target and an opening 1908 into a deposition chamber. For example, referring to FIG. 10, the opening 1908 can correspond to the opening 1410 between the target chamber 1412 and the collection chamber 1406. In the region 1906 between the location 1904 and the opening 1908, for example, the pressure can remain relatively constant. At or near the opening 1908, the pressure can increase significantly, but still remain less than the pressure at the location 1902.

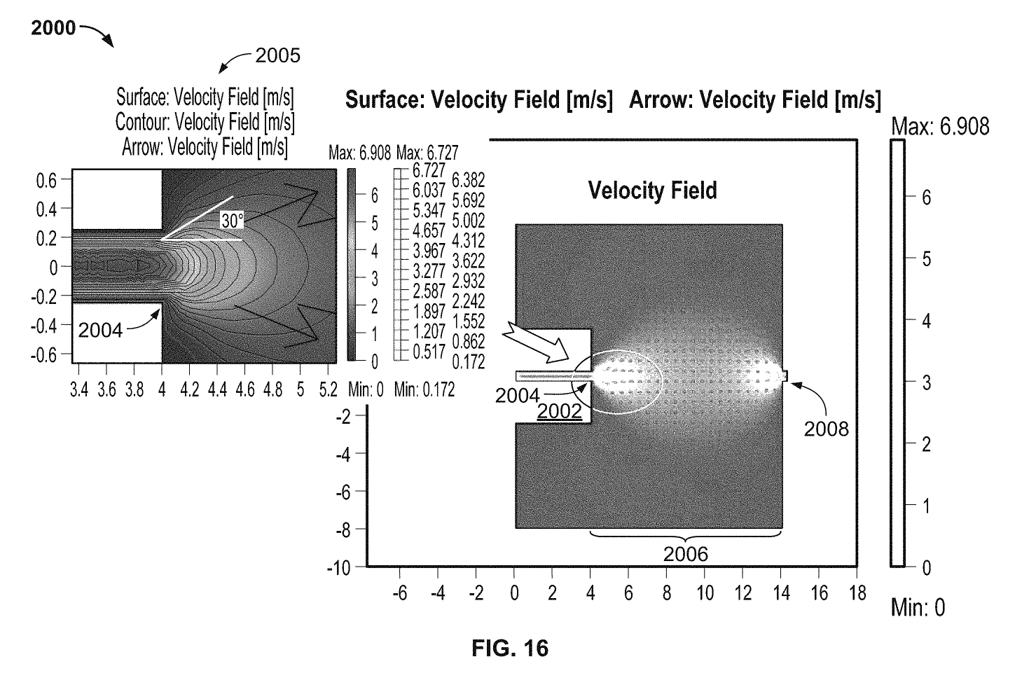

FIG. 16 shows an example velocity field simulation 2000 that indicates the speed and direction of a gas flow through a tube target. The simulation 2000, for example, can show that the velocity of the gas is generally uniform inside of a tube target 2002. A location 2004 can represent the ejection area of the tube target 2002. When the gas reaches the location 2004, the pressure can drop significantly, indicating that the gas flow expands at the tube target's outlet. Furthermore, the direction of flow of the gas can fan out, such as by an angle 2005 of about 30% or more. A region 2006 can represent, for example, the region between the ejection end of the tube target 2002 and an opening 2008 into a deposition chamber. For example, referring to FIG. 10, the opening 2008 can correspond to the opening 1410 between the target chamber 1412 and the collection chamber 1406. In the region 2006 between the location 2004 and the opening 2008, for example, the velocity of the gas can remain relatively constant. At or near the opening 2008, the velocity of the gas can increase significantly as the gas enters the opening 2008.

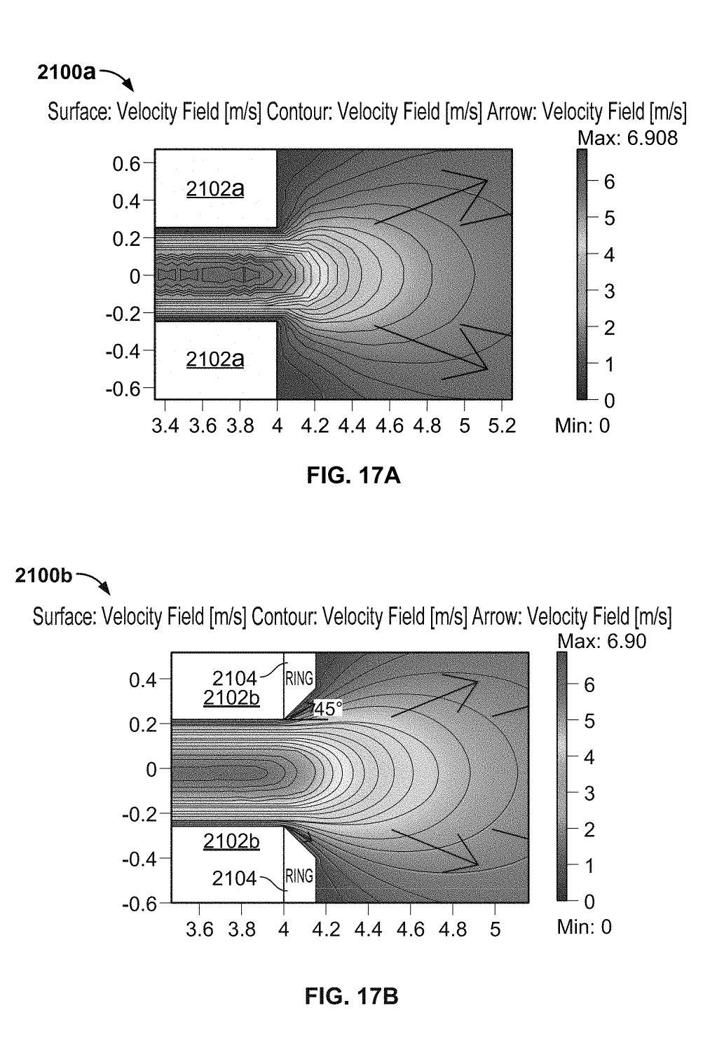

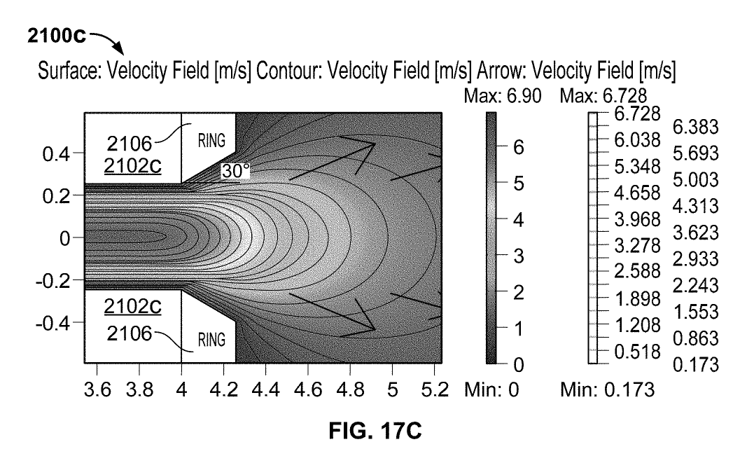

FIGS. 17A-C show example velocity field simulations 2100a-c for gas flow through tube targets 2102a-c, respectively. The targets 2102a-c, which are shown using cross-sectional views, are identical, each having a length of 40 mm. However, a 45-degree-bevel iron ring 2104 can be attached to the end of the target 2102b, and a 30-degree-bevel iron ring 2106 can be attached to the end of the target 2102c. The iron rings 2104 and 2106 can serve to change the magnetic field in and around their corresponding tube targets, including at each outlet hole. The side-by-side comparison of the three velocity field simulations 2100a-c shows example effects of adding iron rings. For example, by adding the iron rings 2104 and 2106 to the targets 2102b and 2102c, respectively, the gas flow can be more concentrated at the center of the tube, as compared to the gas flow out of the target 2102a.

FIG. 18 shows a cross-sectional view of an example magnetic field 2300 that can be produced by magnets 2302 and 2304 in a North-to-North arrangement and an added iron ring. The magnetic field 2300 can be similar to the magnetic field 1800, which can also be produced using a North-to-North arrangement. The magnetic field 2300 can extend beyond the far end of the tube target 2306. A circle 2308 is drawn around lines that represent a portion of the magnetic field 2300. The purpose of the circle 2308 is to point out that any part of the magnetic field that is inside the target 2306 can contribute to the enhancement of plasma.

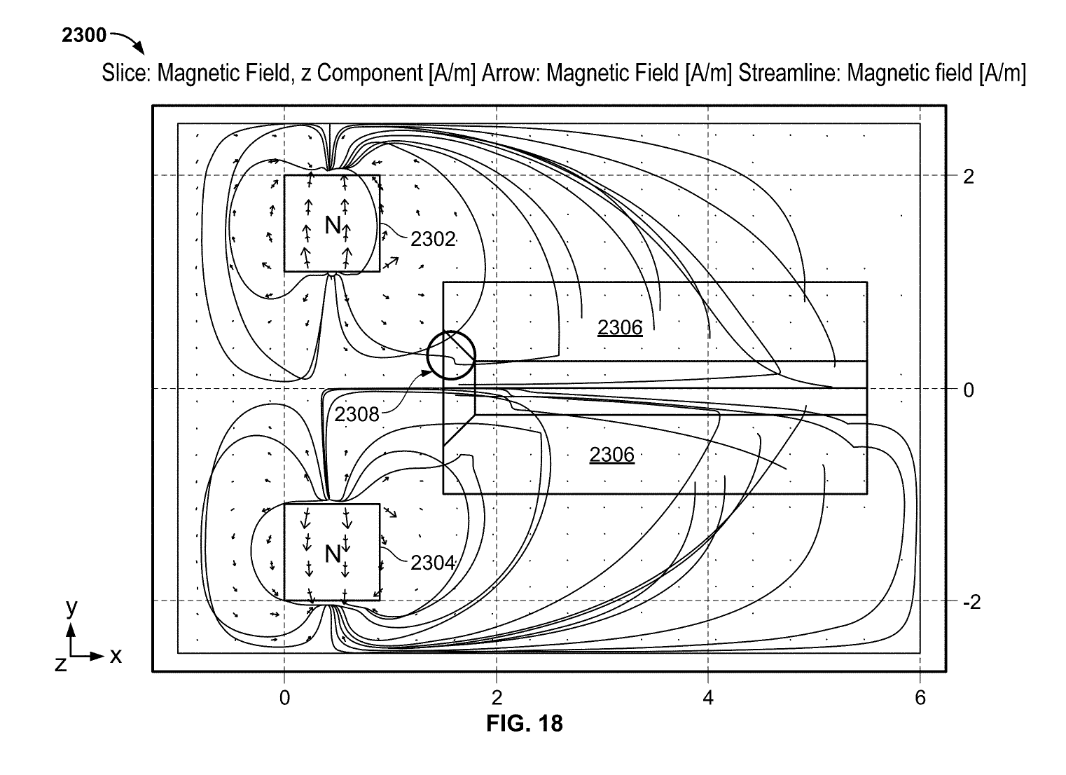

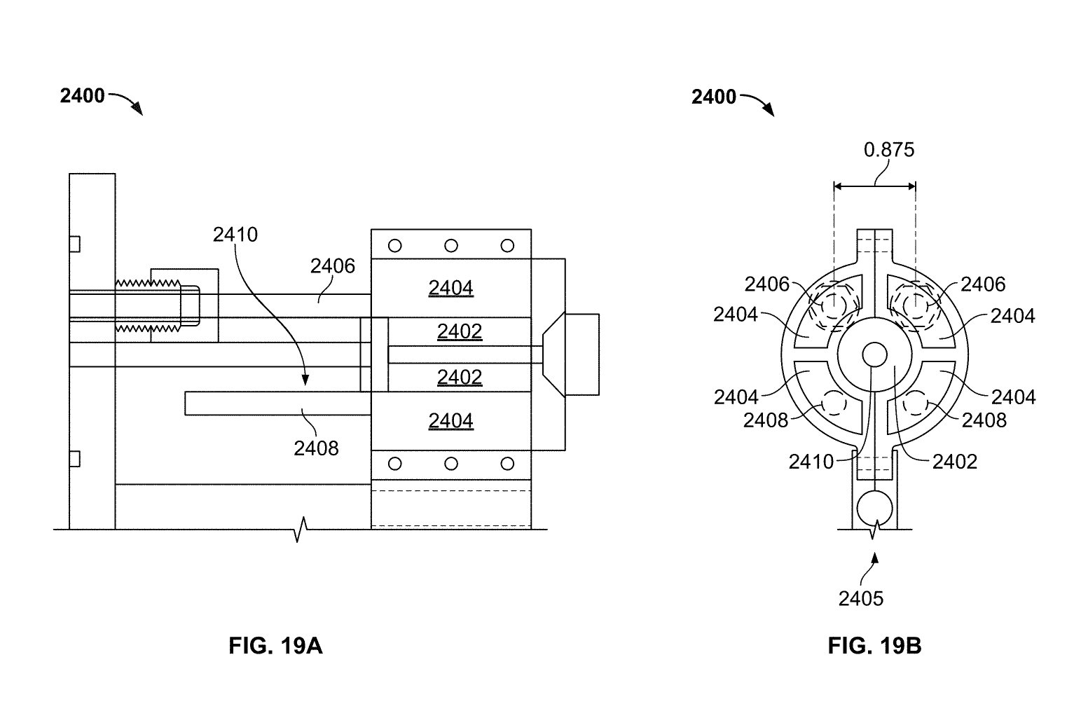

FIGS. 19A and 19B show side views of an example tube target nanoparticle deposition system 2400, and the back view of its cooling part. A tube target 2402 can be surrounded by cooling water 2404. As shown in FIG. 19B which highlights a cooling system 2405, cooling water 2404 can enter the cooling system 2405 through coolant inputs 2406, and exit the cooling system 2405 through coolant outputs 2408. Sputtering gas 2410 can travel through the center of the tube target 2402.

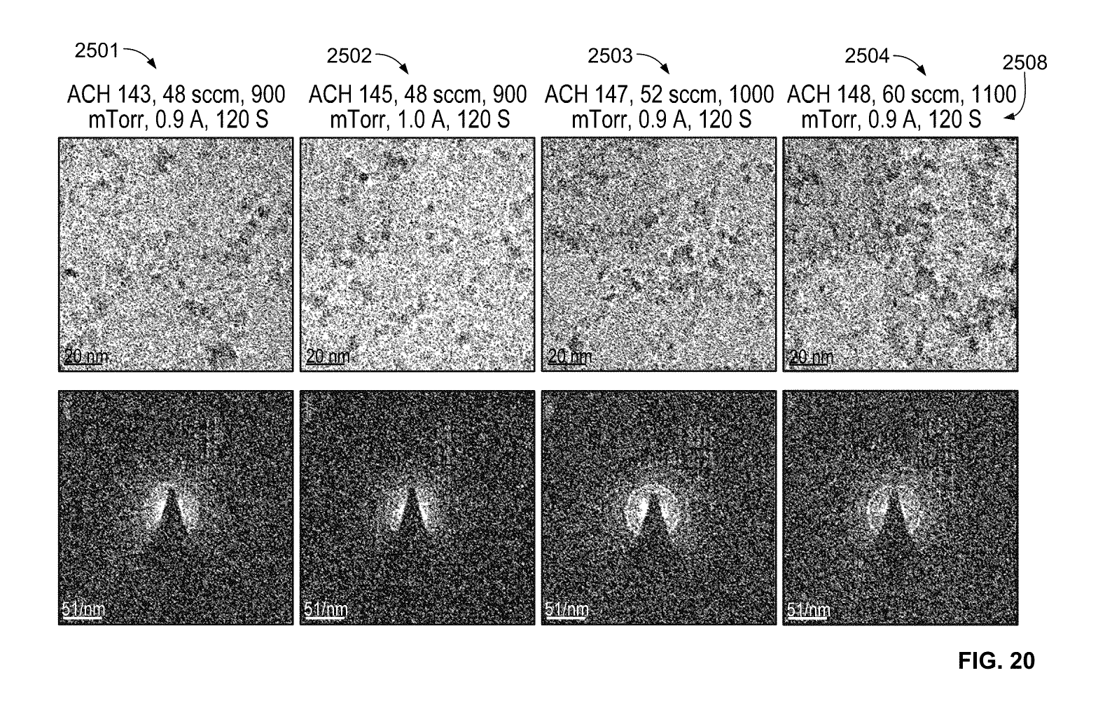

FIG. 20 shows example FeCo nanoparticles that were produced using tube target nanoparticle deposition systems. Each of the samples 2501-2504 includes an image of the nanoparticles and an associated electron diffraction pattern. The samples 2501-2504 were gathered under different conditions, as indicated by headers 2508. For example, the sample 2501 named “ACH 143” used a sputtering gas flow rate of 48 sccm (standard cubic centimeters per minute), an argon gas pressure of 900 mTorr, a sputtering current of 0.9 amps, and a sputtering duration of 120 seconds.

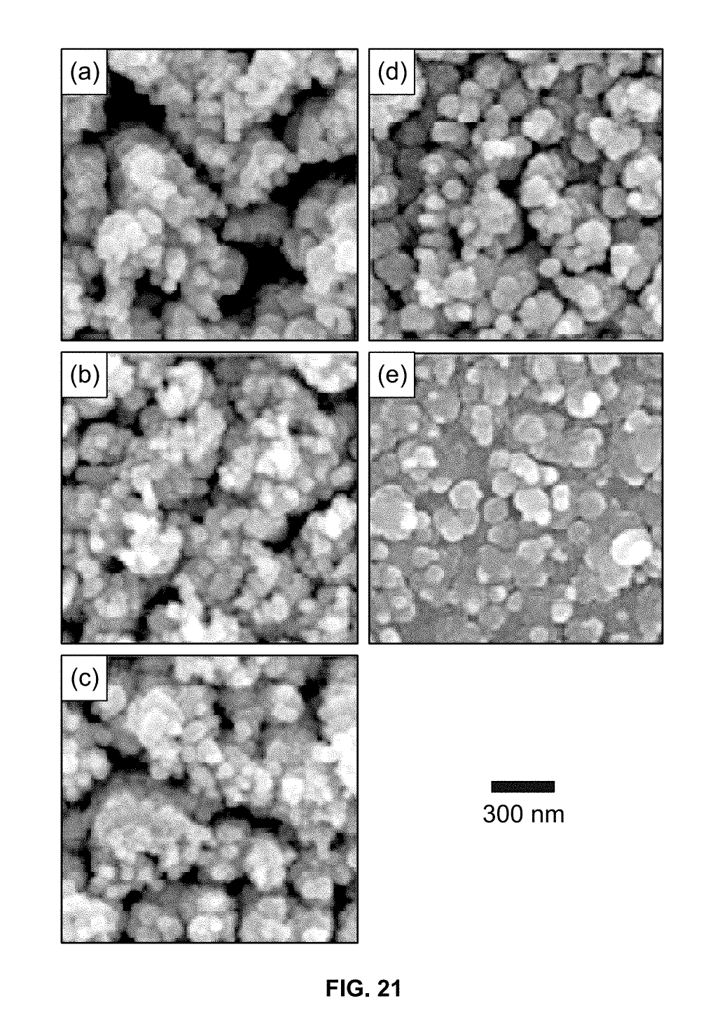

FIG. 21 shows images for example Fe—N nanoparticle samples created using a tube target. The transmission electron microscopy (TEM) images show samples that are the result of depositing for four minutes. The internal size of the tube target was 8 mm. The sputtering rate was about 0.6 mg per hour. Because erosion of the target can occur during the sputtering process, the sputtering area can increase over time.

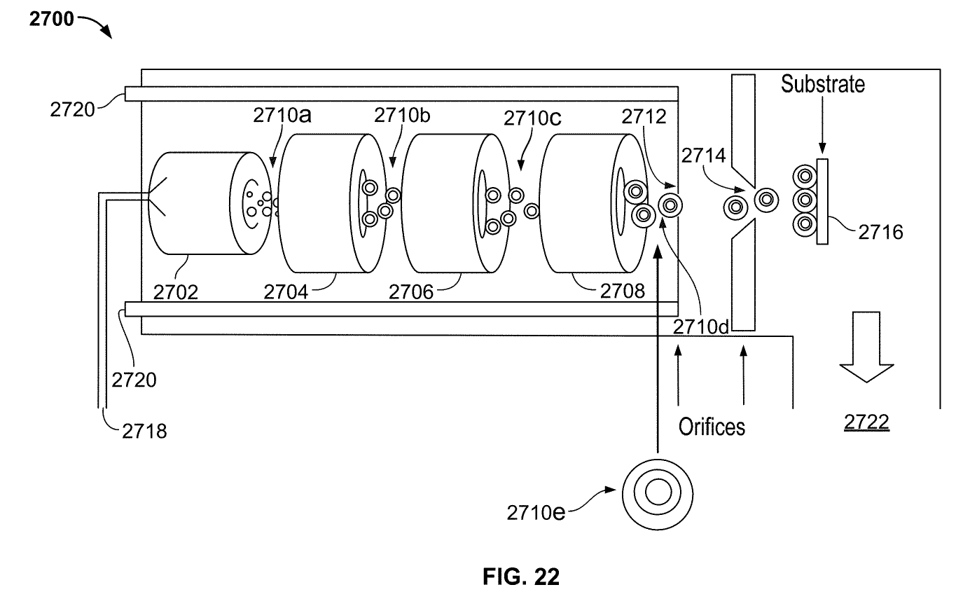

FIG. 22 shows a cross-sectional view of an example nanoparticle deposition system 2700 that uses a nucleation target 2702 and growth targets 2704-2708 for same or different layers on the nucleus. The system 2700 can produce nanoparticles 2710a-2710d that can grow increasingly large in size as they are formed (and grow in and around) the targets 2702-2708. For example, the nanoparticles 2710a can have a relatively small size, having just been formed in the nucleation target 2702. Nanoparticles 2710b and 2710c, which can have one or more shells, can be slightly larger, having been grown in growth targets 2704 and 2706, respectively. Nanoparticles 2710d, which can be larger still and have multiple shells, can be grown in the growth target 2708. A multi-shell nanoparticle 2710e, for example, shown with two shells, can represent the type of particles that can be formed by the system 2700. Multiple-shell nanoparticles possessing multiple functions can be formed by the system 2700, for example, because the targets can use different materials.

For example, the system 2700 shows a separation of nucleation and growth regions within the system 2700, each region using different types of targets (e.g., nucleation and growth targets). Each of the targets 2702-2708 can be controlled separately. The target material used for the targets 2702-2708 can be the same or different material. Both the nucleation target 2702 and the growth targets 2704-2708 can be tube type or facing-target type targets. For example, facing-target type targets can include two targets facing each other, or two pairs of facing targets.

In some implementations, cathode connections can be made to the targets 2702-2708, such as to provide a charge to the targets 2702-2708. Size and spacing of the targets 2702-2708 can be varied to control the formation of core-shell type nanoparticles for any materials by separating the nanoparticles' core and shell growth regions and by using different targets.

In some implementations, orifices can be installed between individual targets to control the gas flow. In some implementations, a carrier gas supply can be used to carry the gas through the system 2700.

Some implementations of the system 2700 can have more or fewer growth targets and more or fewer nucleation targets, such as arranged in different configurations. In some implementations, growth targets can be, for example, tube-shaped targets, facing targets, or some combination of various targets.

The particles 2702-2708, once formed, can travel through one or more orifices 2712 and 2714 and be deposited on a substrate 2716. A sputtering gas 2718 can provide, for example, ionized argon gas into the nucleation target 2702. Cooling liquid 2720 can cool the targets 2702-2708. A pump 2722 can pump gas from the system 2700, keeping the particles 2702-2708 circulating, and helping to pull the particles toward the substrate 2716.

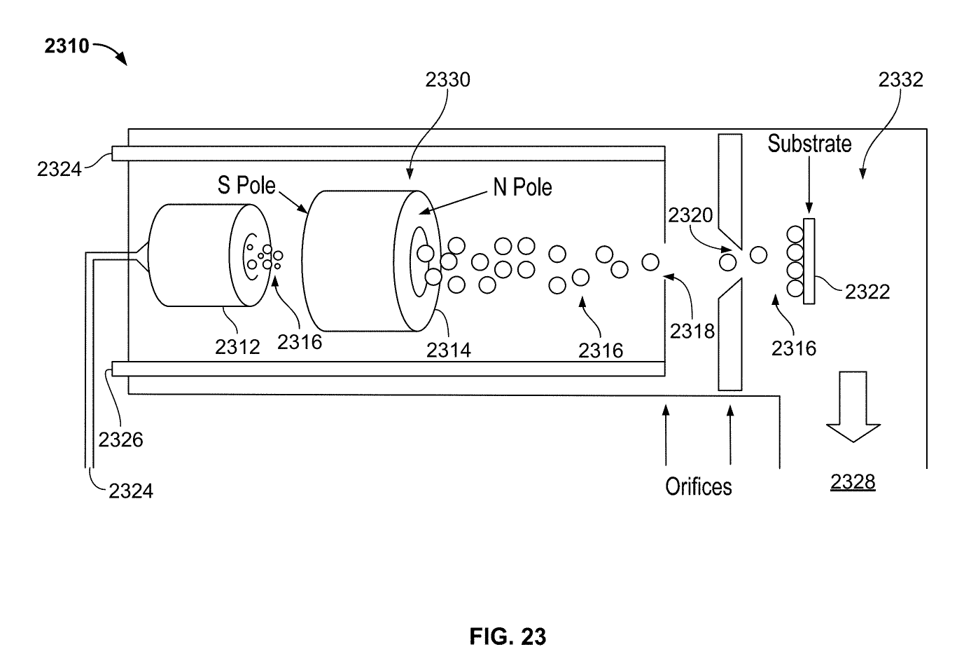

FIG. 23 shows a cross-sectional view of an example nanoparticle deposition system 2310 that uses a nucleation target 2312 and a cylinder-shaped plasma control magnet 2314. The system 2310 can produce nanoparticles 2316 that can grow in the nucleation target 2312. The particles 2316, once formed, can travel through the cylinder-shaped plasma control magnet 2314 and through orifices 2318-2320 and be deposited on a substrate 2322. The plasma control magnet 2314 can control the density of the plasma and the length of the plasma region, which in turn can control the crystallization process of the nanoparticles. A sputtering gas 2324 can provide, for example, ionized argon gas into the nucleation target 2312. Cooling liquid 2326 can cool the area around the target 2312 and the cylinder-shaped plasma control magnet 2314. A pump 2328 can pump gas from the system 2310, keeping the particles 2316 circulating, and helping to pull the particles toward the substrate 2318.

A first pressure 2330 in the area around the target 2312 and the cylinder-shaped plasma control magnet 2314 can be higher than a second pressure 2332 in an area around the substrate 2318.

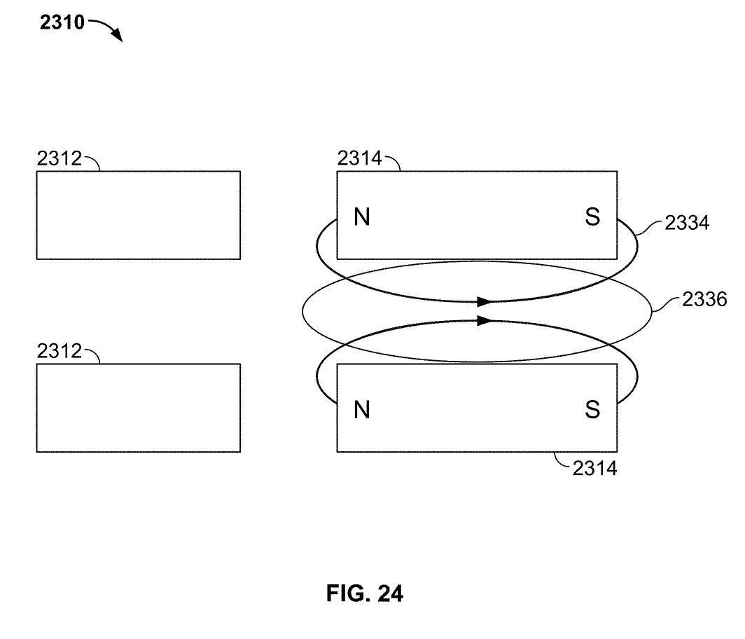

FIG. 24 shows a more detailed cross-sectional view of the nucleation target 2312 and the cylinder-shaped plasma control magnet 2314. A magnetic field 2334 is produced by the cylinder-shaped plasma control magnet 2314. The magnetic field 2334 extends into a plasma region 2336, the region through which the particles 2316 travel from the target 2312 to the substrate 2318. Controlling the motion of charged entities in the plasma the magnetic field 2334 can effectively control the plasma.

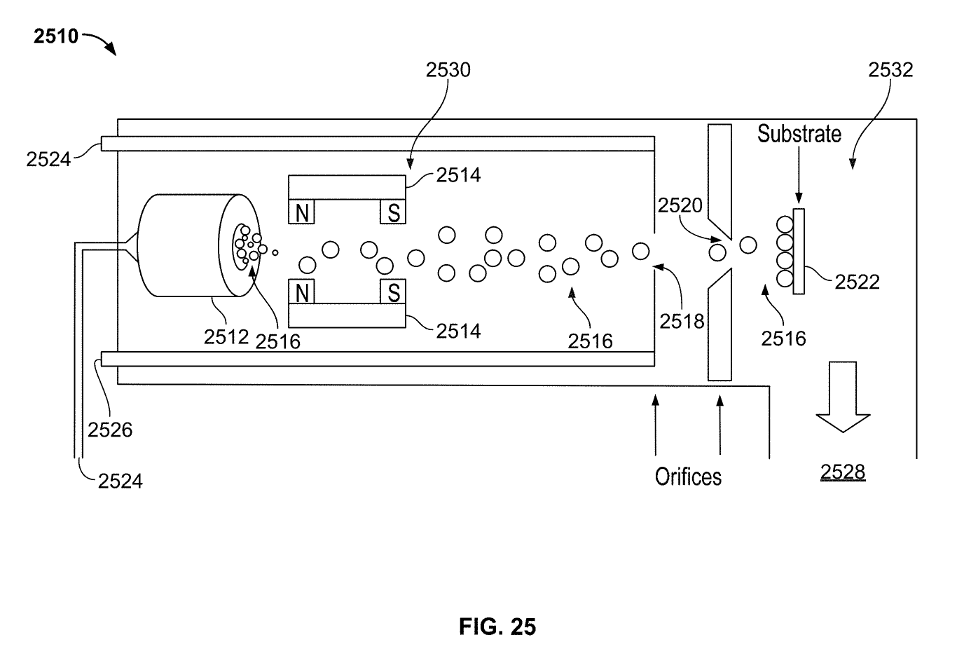

FIG. 25 shows a cross-sectional view of an example nanoparticle deposition system 2510 that uses a nucleation target 2512 and a U-shaped plasma control magnet 2514. The system 2510 can produce nanoparticles 2516 that can grow in the nucleation target 2512. The particles 2516, once formed, can travel through the U-shaped plasma control magnet 2514 and through orifices 2518-2520 and be deposited on a substrate 2522. The U-shaped magnet 2514 is an alternative way to supply a magnetic field to control the plasma. A sputtering gas 2524 can provide, for example, ionized argon gas into the nucleation target 2512. Cooling liquid 2526 can cool the area around the target 2512 and the U-shaped plasma control magnet 2514. A pump 2528 can pump gas from the system 2510, keeping the particles 2516 circulating, and helping to pull the particles toward the substrate 2518.

A first pressure 2530 in the area around the target 2512 and the U-shaped plasma control magnet 2514 can be higher than a second pressure 2532 in an area around the substrate 2518.

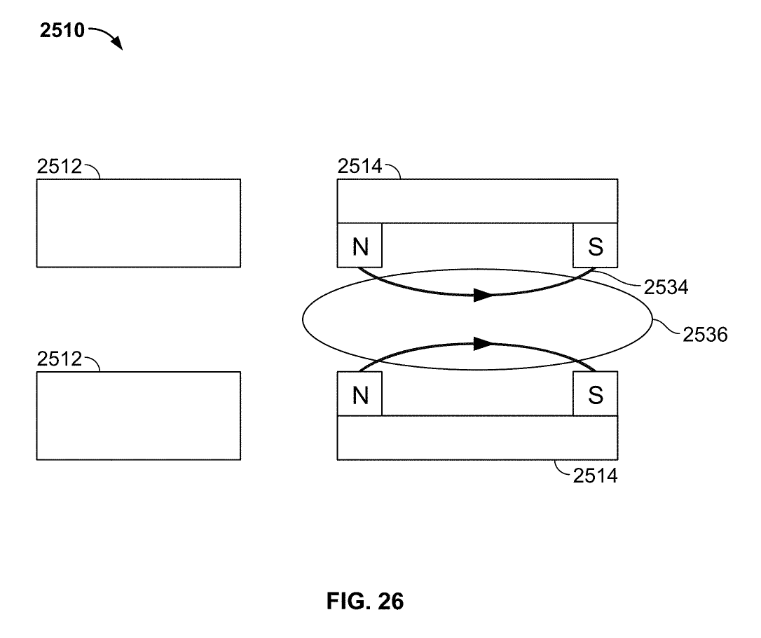

FIG. 26 shows a more detailed cross-sectional view of the nucleation target 2512 and the U-shaped plasma control magnet 2514. A magnetic field 2534 is produced by the U-shaped plasma control magnet 2514. The magnetic field 2534 extends into a plasma region 2536, the region through which the particles 2516 travel from the target 2512 to the substrate 2518.

In some implementations, other shapes can be used for targets such as the nucleation target 2512 and the nucleation target 2512. In some implementations, other shapes can be used for plasma control magnets such as the cylinder-shaped plasma control magnet 2514.

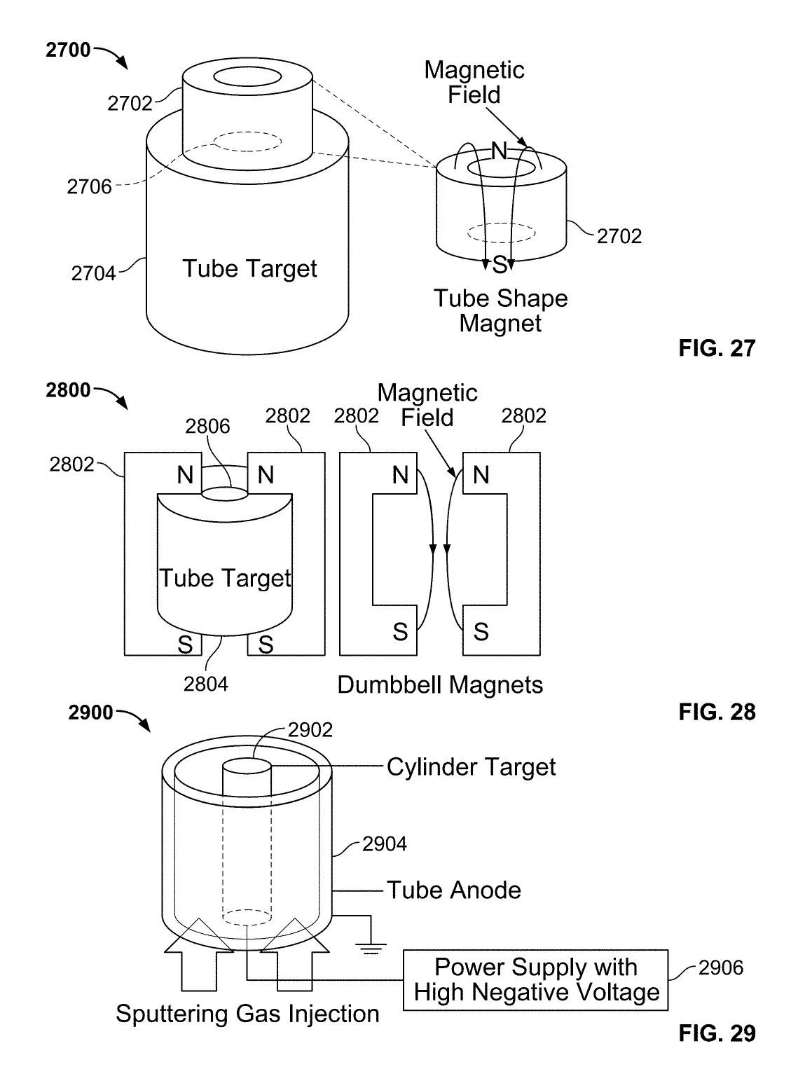

FIG. 27 shows a nanoparticle fabrication source 2700 using a tube-shaped magnet 2702. In this example, the magnet 2702 has a tube shape, with its N and S poles at the end of the tube.

The nanoparticle fabrication source 2700 in this example has a tube target 2704. The tube-shaped magnet 2702 can be attached on a surface of the tube target so that either the N pole or S pole faces the target. In some implementations, the magnet 2702 can supply extra plasma to the nanoparticle fabrication source 2700 than otherwise. For example, the magnet 2702 can thereby affect particle growth.

One advantage of the nanoparticle fabrication source 2700 in some implementations is that the tube-shaped magnet 2702 can supply an essentially uniform magnetic field near an outlet 2706 of the tube target 2704. The magnetic field inside the magnet 2702 is parallel to the axis of the tube. During a sputtering process, for example, electrons exit the tube target and enter the tube magnet. In doing so, the electrons are confined by the magnetic field inside the magnet. As a result, the electrons can continuously ionize argon atoms and generate extra plasma inside the magnet. For example, extra plasma can supply energy to the nanoparticles being formed in this region and facilitate crystallization.

FIG. 28 shows a nanoparticle fabrication source 2800 using a dumbbell magnet 2802. In some implementations, two or more dumbbell magnets are clamped on a tube target 2804. For each dumbbell magnet 2800, the N and S poles are on its two ends. In some implementations, the magnetic field is stable at high temperatures and is essentially uniform inside and outside the tube target 2804. For example, temperatures of about 50° C. to 400° C. can be used. The magnetic field can supply extra plasma near an outlet 2806 of the tube target. Such extra plasma can facilitate crystallization of the nanoparticles by supplying energy to them.

FIG. 29 shows a nanoparticle fabrication source 2900 using a cylinder target 2902 in source center as the cathode. In this example, the layout is in a sense opposite to some designs using a tube target. Here, a hollow anode 2904 of the nanoparticle fabrication source 2900 is hollow, has a cylinder shape and is grounded. The target 2902 in this example has a solid cylinder shape and is placed inside the hollow cylinder anode, such as in the center of the hollow cylinder. A high negative voltage is connected to the cylinder target by a power supply 2906. For example, voltages of about −150 V to −500 V can be used.

During fabrication, the sputtering gas (e.g., argon) is injected into the space between the cylinder target 2902 and the hollow anode 2904, and flows through the anode. A strong electrical field generated by the voltage differential between the anode and target will ionize the gas and generate plasma. The strength of the electrical field depends on the gap between the cylinder target and the hollow anode. For example, electrical fields of about 2.14×10⁴ V/m to 7.14×10⁴ V/m can be used. The positive ions inside the plasma will be accelerated by the electrical field and impact on the target to release atoms from the target. The released atoms will be carried out of the cylinder target 2902 by the gas. When the released atoms exit the target, they will condense at high pressure to grow into nanoparticles. For example, pressures of about 0.3 Torr to 10 Torr can be used. In some situations, extra plasma is provided outside the hollow anode 2904 and the plasma can crystallize the nanoparticles by supplying energy to them.

Experimentation with various implementations of some deposition systems described in this document has provided various measurable results. For example, using a target tube with a diameter of 25 mm, a maximum deposition rate of 0.35 mg/hr was achieved. The target usage was over 90%, which is an improvement of traditional target usage that typically can be in the range of 5%. Under these conditions, there was no need to change the target for at least 500 hours.

A number of implementations have been described. Nevertheless, it will be understood that various modifications may be made without departing from the spirit and scope of this disclosure.

1.-37. (canceled)

38. A multi-shell nanoparticle comprising a core and two or more shells.

39. The multi-shell nanoparticle of claim 38, wherein the core and one or more of the shells comprise the same material.

40. The multi-shell nanoparticle of claim 38, wherein the core and one or more of the shells comprise different materials.

41. The multi-shell nanoparticle of claim 38, wherein the core comprises Fe or FeCo.

42. The multi-shell nanoparticle of claim 38, wherein the one or more of the shells comprise a material selected from Co, FeCo, FeCoO, Au, Ag, N, C, and SiO₂.

43. The multi-shell nanoparticle of claim 38, wherein the multi-shell nanoparticle is selected from a C nanoparticle, a FeCo nanoparticle, a FeCo—FeCoO nanoparticle, a FeCo—Au nanoparticle, a FeCo—SiO₂ nanoparticle, a Fe—Ag nanoparticle, a Co—Au nanoparticle, and a Fe—Au nanoparticle.
